(19) United States
(12) Patent Application Publication
(10) Pub. No.: US 2025/0275416 A1
(43) Pub. Date: Aug. 28, 2025

(54) Display Apparatus

(71) Applicant: LG Display Co., Ltd., Seoul (KR)

(72) Inventors: Giyoun Kim, Paju-si (KR); Jungwoo Lee, Paju-si (KR); Jaehyoung Park, Paju-si (KR)

(21) Appl. No.: 19/060,993

(22) Filed: Feb. 24, 2025

(30) Foreign Application Priority Data
Feb. 26, 2024 (KR) 10-2024-0027330

(51) Int. Cl. H10K 59/80; H10K 59/121; H10K 59/126; H10K 59/40

(52) U.S. Cl. CPC H10K 59/871; H10K 59/8791; H10K 59/1213; H10K 59/1216; H10K 59/126; H10K 59/40

(57) ABSTRACT

A display apparatus according to one embodiment of the present disclosure may include a display panel, a cover layer on the display panel, and a bonding layer including a main bonding layer on the cover layer and a nitrogen reactive bonding layer on the main bonding layer, wherein a content of nitrogen atom of the nitrogen reactive bonding layer may be greater than a content of nitrogen atoms of the main bonding layer.

### CROSS REFERENCE TO RELATED APPLICATIONS

This application claims priority under 35 U.S.C. § 119 (a) to the Republic of Korea Patent Application No. 10-2024-0027330, filed in the Republic of Korea on Feb. 26, 2024, the entire contents of which are hereby expressly incorporated by reference into the present application.

### BACKGROUND

The present specification relates to a display apparatus.

### Description of the Related Art

As the information society develops, various demands for display apparatuses for displaying images are increasing, and various types of display apparatuses such as liquid crystal display (LCD) apparatuses and organic light emitting diode (OLED) display apparatuses are utilized.

Among the display apparatuses, there is an advantage in that the OLED displays as the self-luminous types have superior viewing angles and contrast ratios than the LCDs, and are lighter and thinner and have low power consumption because they do not require a separate backlight. In addition, there is an advantage in that the OLED displays may drive at a low direct current voltage, have a fast response speed, and low manufacturing costs.

### SUMMARY OF THE DISCLOSURE

The present disclosure is directed to providing a display apparatus in which a bonding layer may be easily peeled from a base substrate to which the bonding layer is attached.

The present disclosure is directed to providing a display apparatus in which ultraviolet rays may be radiated to peel a bonding layer from a base substrate without emitting heat, thereby preventing the conflict with high temperature conditions during reliability evaluation.

The aspects of the present disclosure are not limited to the above-described aspect, and other technical aspects may be inferred from the embodiments below.

A display apparatus according to one embodiment of the present disclosure comprises a display panel, a cover layer on the display panel, and a bonding layer comprising a main bonding layer on the cover layer and a nitrogen reactive bonding layer on the main bonding layer. A content of nitrogen atoms (N) of the nitrogen reactive bonding layer is greater than a content of nitrogen atoms (N) of the main bonding layer.

A display apparatus according to another embodiment of the present disclosure comprises a display panel, a main bonding layer on the display panel, a cover layer on the main bonding layer, and a nitrogen reactive bonding layer on the cover layer. A content of nitrogen atoms (N) of the nitrogen reactive bonding layer is greater than a content of nitrogen atoms (N) of the main bonding layer.

A display apparatus according to still another embodiment of the present disclosure comprises a display panel, a first stretchable board on the display panel, a main bonding layer on the first stretchable board, a second stretchable board on the main bonding layer, and a nitrogen reactive bonding layer on the second stretchable board. A content of nitrogen atoms of the nitrogen reactive bonding layer is greater than a content of nitrogen atoms of the main bonding layer.

Details of other embodiments are included in a detailed description and accompanying drawings.

According to the embodiments of the present disclosure, since the nitrogen reactive bonding layer is formed of the ultraviolet reactive adhesive, the reliability evaluation at high temperatures of the product can be easily performed.

According to the embodiments of the present disclosure, since the nitrogen reactive bonding layer can be separated from the base substrate by the ultraviolet radiation method, it is possible to prevent the occurrence of physical damage at the edge portion of the base substrate.

According to the embodiments of the present disclosure, since the physical damage at the edge portion of the base substrate does not occur, the base substrate can be reused, thereby significantly reducing the discard rate of the base substrate. Therefore, it is possible to eco-friendly manufacture or produce the display apparatus.

However, the effects obtainable from the present disclosure are not limited to the above-described effects, and other effects that are not mentioned will be able to be clearly understood by those skilled in the art to which the present disclosure pertains from the following description.

Although the embodiments have been described above with reference to the accompanying drawings, those skilled in the art to which the present disclosure pertains will be able to understand that the above-described technical configuration can be carried out in other specific forms without changing the technical spirit or essential features thereof. Therefore, it should be understood that the above-described embodiments are illustrative and not restrictive in all respects. In addition, the scope of the embodiments is indicated by the claims to be described below rather than the detailed description. In addition, the meaning and scope of the claims and all changed or modified forms derived from the equivalent concept thereof should be construed as being included in the scope of the embodiments.

### BRIEF DESCRIPTION OF THE DRAWINGS

The accompanying drawings, which are comprised to provide a further understanding of the disclosure, are incorporated in and constitute a part of this application, illustrate embodiments of the disclosure and together with the description serve to explain principles of the disclosure.

FIG. 1 is a cross-sectional view showing a substrate, a bonding layer, and a film according to one embodiment of the present specification.

FIG. 2 is a cross-sectional view showing a seed space for peeling at an edge portion between the substrate and the bonding layer according to FIG. 1.

FIG. 3 is a schematic view showing peeling the bonding layer according to FIG. 2 from the substrate through heating.

FIG. 4 is a schematic view showing peeling the bonding layer according to FIG. 2 from the substrate through an ultraviolet reaction.

FIG. 5 is a schematic view showing peeling the bonding layer according to FIG. 2 from the substrate through an aqueous method.

FIG. 6 is a perspective view showing a tray, a bonding layer, and LED chips according to another embodiment of the present specification.

FIG. 7 is a perspective view showing the tray and the bonding layer after the LED chips of FIG. 6 are transferred.

FIG. 8 is a perspective view showing a tray, a bonding layer, and LED chips according to another embodiment of the present specification.

FIG. 9 is a cross-sectional view along line A-A′ in FIG. 8.

FIG. 10 is a cross-sectional view showing a case in which ultraviolet rays are radiated to the bonding layer according to FIG. 9.

FIG. 11 is a schematic view showing that the bonding layer is peeled from the tray when ultraviolet rays are radiated according to FIG. 10.

FIG. 12 is a perspective view of a display apparatus according to another embodiment of the present specification.

FIG. 13 is a cross-sectional view showing a folded state of the display apparatus according to FIG. 12.

FIG. 14 is a cross-sectional view along line B-B′ in FIG. 12. FIG. 15 is a cross-sectional view of a display panel according to FIG. 14.

FIG. 16 is an enlarged cross-sectional view of area Q1 in FIG. 14.

FIG. 17 is a cross-sectional view showing a case in which ultraviolet rays are radiated to the display apparatus according to FIG. 16.

FIG. 18 is a schematic view showing that a second bonding layer is peeled from a polarization layer when ultraviolet rays are radiated according to FIG. 17.

FIG. 19 is a cross-sectional view of a display apparatus according to another embodiment of the present specification.

FIG. 20 is an enlarged cross-sectional view of area Q2 in FIG. 19.

FIG. 21 is a cross-sectional view showing a case in which ultraviolet rays are radiated to the display apparatus according to FIG. 20.

FIG. 22 is a schematic view showing that a third bonding layer is peeled from a cover layer when ultraviolet rays are radiated according to FIG. 21.

FIG. 23 is a cross-sectional view of a display apparatus according to still another embodiment of the present specification.

FIG. 24 is an enlarged cross-sectional view of area Q3 in FIG. 23.

FIG. 25 is a cross-sectional view showing a case in which ultraviolet rays are radiated to the display apparatus according to FIG. 24.

### DETAILED DESCRIPTION OF THE EMBODIMENTS

Hereinafter, embodiments will be described with reference to the accompanying drawings. In the disclosure, when a first component (or an area, a layer, a portion) is described as “on,” “connected,” or “coupled to” a second component, that means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as “first” and “second” may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Embodiments of the present specification may include a base substrate, and a bonding layer attached to the base substrate. Although the base substrate may include a substrate to which the bonding layer is attached, a film, a tray, an insulating layer, a metal layer, the embodiments of the present specification are not limited thereto. The following embodiments exemplify a base substrate specified in various products and a bonding layer on the base substrate.

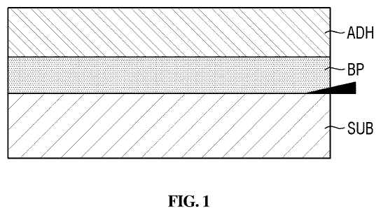

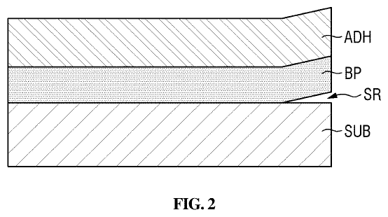

FIG. 1 is a cross-sectional view showing a substrate, a bonding layer, and a film according to one embodiment of the present specification. FIG. 2 is a cross-sectional view showing that a seed space for peeling at an edge portion between the substrate and the bonding layer according to FIG. 1 is secured. FIGS. 1 and 2 show a case in which a base substrate includes a substrate SUB.

Referring to FIGS. 1 and 2, the substrate SUB according to one embodiment may be bonded to a film ADH through a bonding layer BP. Although FIGS. 1 and 2 show the substrate SUB applied as the base substrate, the embodiments of the present disclosure are not limited thereto. Although the substrate SUB may include a plastic substrate or a glass substrate, the embodiments of the present disclosure are not limited thereto. For example, the plastic substrate may be a plastic substrate made of one of polyimide, polyethersulfone, polyethylene terephthalate, and polycarbonate, and the embodiments of the present specification are not limited thereto. For example, the glass substrate may include glass, quartz, and the embodiments of the present disclosure are not limited thereto.

Although FIGS. 1 and 2 show the film ADH disposed on the bonding layer BP, any member other than the film ADH may be disposed.

The bonding layer BP may bond the substrate SUB and the film ADH. The bonding layer BP may include a transparent adhesive. For example, although the transparent adhesive may be a transparent resin (OCR) or a transparent adhesive (OCA), the embodiments of the present specification are not limited thereto.

The bonding layer BP is attached to an upper surface of the substrate SUB, and when the bonding layer BP is incorrectly attached in the process of attaching the bonding layer BP to the upper surface of the substrate SUB, the bonding layer BP needs to be peeled from the substrate SUB. The present specification exemplifies that the bonding layer BP is peeled from the substrate SUB when the bonding layer BP is incorrectly attached in the process of attaching the bonding layer BP to the upper surface of the substrate SUB, but in various cases, the bonding layer BP may be peeled from the substrate SUB.

To peel the bonding layer BP from the upper surface of the substrate SUB, as shown in FIG. 1, it may be necessary to form a peeling space between the bonding layer BP and the substrate SUB. Although FIG. 1 shows the peeling space formed at an edge portion between the bonding layer BP and the substrate SUB through a scribing process, the embodiments of the present specification are not limited thereto.

As shown in FIG. 2, a peeling space SR may be formed at the edge portion between the bonding layer BP and the substrate SUB. In the peeling space SR, the bonding layer BP and the substrate SUB may be spaced a predetermined distance from each other.

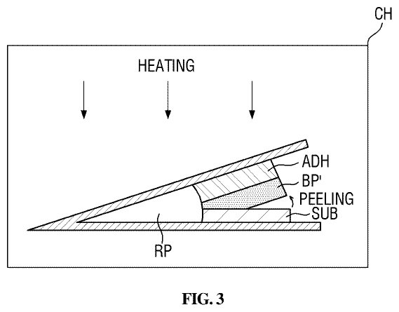

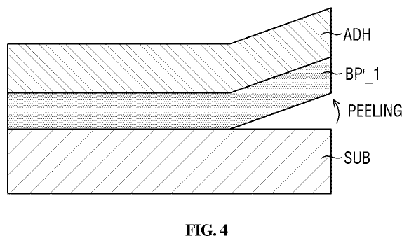

The following FIGS. 3 to 5 show examples in which the bonding layer BP of FIG. 2 is peeled from the substrate SUB through various methods.

FIG. 3 is a schematic view showing peeling the bonding layer according to FIG. 2 from the substrate through heating.

Referring to FIG. 3, a bonding layer BP′ may be peeled from the substrate SUB through heating that emits heat. The substrate SUB, the bonding layer BP (see FIG. 2), and the film ADH may be positioned in a high temperature oven CH. A lower plate of a rework plate RP may be attached under the substrate SUB. An upper plate of the rework plate RP may be attached above the film ADH. End portions of the lower plate and upper plate of the rework plate RP may be connected. Although the high temperature oven CH may be about 80° C. or higher, the embodiments of the present disclosure are not limited thereto. The bonding layer BP (see FIG. 2) may have reduced adhesive strength at about 80° C. or higher. When the adhesive strength of the bonding layer BP is reduced (see BP′ in FIG. 3), the bonding layer BP′ may be peeled from the substrate SUB as the upper plate of the rework plate RP moves upward. Although the adhesive strength of the bonding layer BP′ is reduced in a high temperature environment, the peeling space SR of FIG. 2 may be required to peel the bonding layer BP′ with reduced adhesive strength from the substrate SUB.

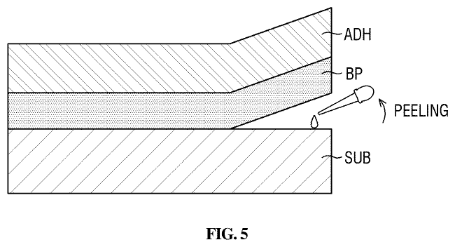

FIG. 4 is a schematic view showing peeling the bonding layer according to FIG. 2 from the substrate through an ultraviolet reaction.

Referring to FIG. 4, the bonding layer BP′_1 may be peeled from the substrate SUB through an ultraviolet reaction. The bonding layer BP of FIG. 2 may be an ultraviolet reactive adhesive. Under ultraviolet wavelength conditions of about 365 nm and 2000 mJ/cm², the bonding layer BP may have reduced adhesive strength depending on an ultraviolet radiation time. For example, it can be confirmed that the adhesive strength of the bonding layer BP with the substrate SUB is about 1000 gf/inch and the adhesive strength is gradually reduced up to 1 hour of the radiation time to have the adhesive strength of about 200 gf/inch.

When the adhesive strength of the bonding layer BP is reduced (see BP′_1 in FIG. 4), the bonding layer BP′_1 may be peeled from the substrate SUB. Although the adhesive strength of the bonding layer BP′_1 is reduced through an ultraviolet reaction, the peeling space SR of FIG. 2 may be required to peel the bonding layer BP′_1 with reduced adhesive strength from the substrate SUB.

FIG. 5 is a schematic view showing peeling the bonding layer according to FIG. 2 from the substrate through an aqucous method.

Referring to FIG. 5, the bonding layer BP may be peeled from the substrate SUB by the aqueous method that allows water to penetrate the interface between the bonding layer BP and the substrate SUB. The aqueous method may be used for peeling when a surface of an object to which the bonding layer BP is attached is hydrophilic. For example, when the substrate SUB is made of a glass material, a surface of the glass is hydrophilic, and thus the bonding layer BP may be peeled from the substrate SUB by the aqueous method. Even in this case, the peeling space SR that allows water to penetrate the interface between the bonding layer BP and the substrate SUB may be required. For another example, when the substrate SUB made of a plastic material is applied as the base substrate, the bonding layer BP may not be peeled from the substrate SUB by the aqueous method because the plastic is hydrophobic.

As described in FIGS. 3 to 5, it may be necessary to secure the peeling space SR (see FIG. 2) between the bonding layer BP and the substrate SUB in each of the heating method, the ultraviolet reaction method, and the aqueous method. When the peeling space SR is formed through a scribing process, scratches may occur on the surface of the substrate SUB. Therefore, even when the bonding layer BP is peeled from the substrate SUB, it may be difficult to reuse the substrate SUB.

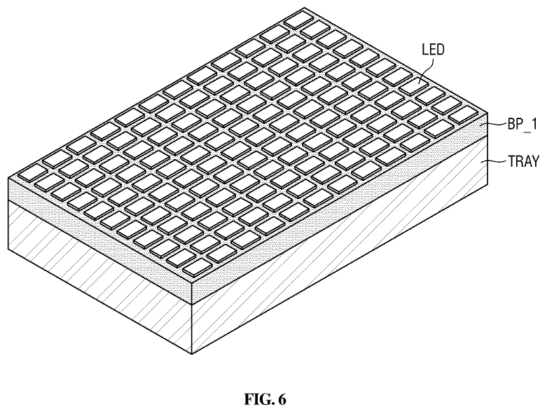

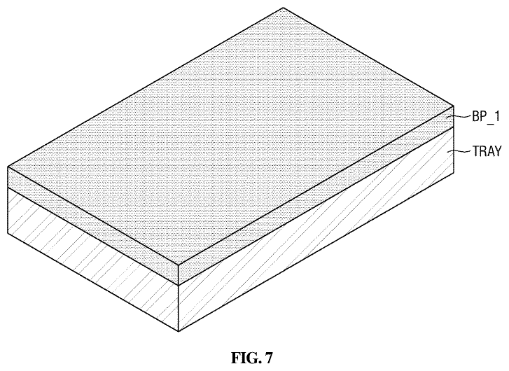

FIG. 6 is a perspective view showing a tray, a bonding layer, and LED chips according to another embodiment of the present specification. FIG. 7 is a perspective view showing the tray and the bonding layer after the LED chips of FIG. 6 are transferred. Although FIGS. 6 and 7 show a case in which the base substrate is applied to a tray TRAY, the embodiments of the present disclosure are not limited thereto.

Referring to FIGS. 6 and 7, a bonding layer BP_1 may be disposed on the tray TRAY. A plurality of LED chips LED are attached to the bonding layer BP_1. The plurality of LED chips LED may be attached to the bonding layer BP_1 on the tray TRAY and transported or transferred to each pixel of the display apparatus. FIG. 7 shows that the plurality of LED chips LED are transferred from the bonding layer BP_1 to each pixel of the display apparatus so that only the bonding layer BP_1 is left on the tray TRAY. Although the LED chip LED may be a micro LED or a mini LED, the embodiments of the present disclosure are not limited thereto.

To transport or transfer other LED chips LED, the attached bonding layer BP_1 of FIG. 7 needs to be removed from the tray TRAY, another bonding layer BP_1 needs to be attached to the tray TRAY, and it may be difficult to remove the bonding layer BP_1. To remove the bonding layer BP_1, the heating method, the ultraviolet reaction method, and the aqueous method according to FIGS. 3 to 5 may be applied, but even in this case, it is necessary to secure the peeling space SR (see FIG. 2) between the bonding layer BP_1 and the tray TRAY, and when the peeling space SR is formed through the scribing process, scratches may occur on the surface of the tray TRAY. Therefore, even when the bonding layer BP_1 is peeled from the tray TRAY, it may be difficult to reuse the scratched tray TRAY.

Hereinafter, a peeling method that does not cause physical damage to the substrate SUB or the tray TRAY even when the bonding layers BP and BP_1 above the substrate SUB of FIG. 1 or the tray TRAY of FIG. 6 are removed will be described.

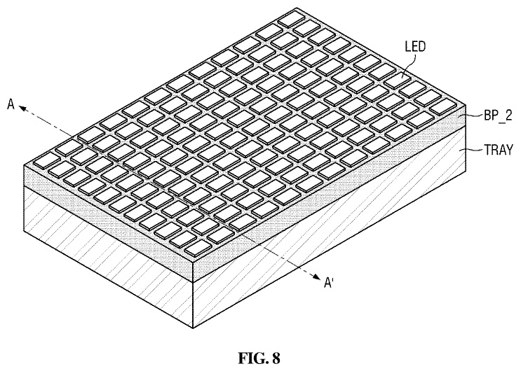

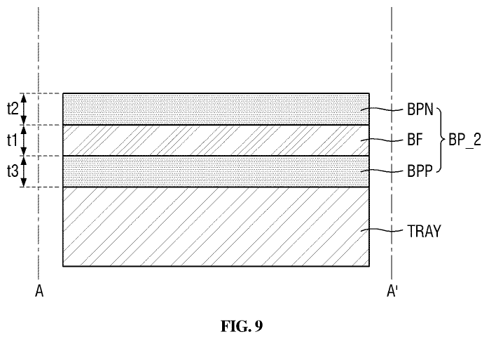

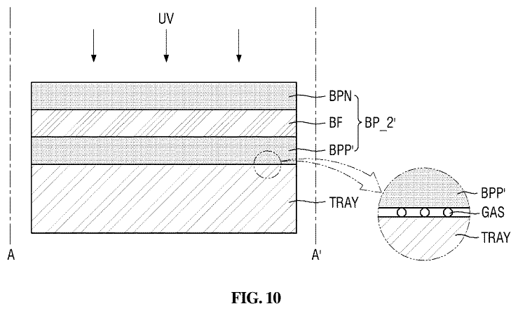

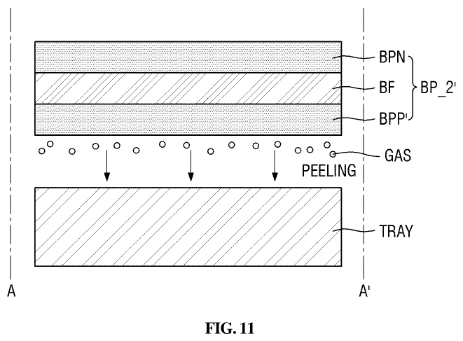

FIG. 8 is a perspective view showing a tray, a bonding layer, and LED chips according to another embodiment of the present disclosure. FIG. 9 is a cross-sectional view along line A-A′ in FIG. 8. FIG. 10 is a cross-sectional view showing a case in which ultraviolet rays are radiated to the bonding layer according to FIG. 9. FIG. 11 is a schematic view showing that the bonding layer is peeled from the tray when ultraviolet rays are radiated according to FIG. 10.

Referring to FIGS. 9 to 11, a bonding layer BP_2 may include a base film BF, a nitrogen reactive bonding layer BPP between the base film BF and the tray TRAY, and a main bonding layer BPN on the base film BF. Although the thickness (t1+t2+t3) of the bonding layer BP_2 may range from about 350 μm to about 500 μm, the embodiments of the present disclosure are not limited thereto.

Although the base film BF may be made of polyimide (PI), (poly) norbornene, high heat-resistant polyethylene terephthalate (PET), an epoxy resin, (poly) urethane, the embodiments of the present disclosure are not limited thereto. For another example, although the base film BF may be made of a copolymer, the embodiments of the present specification are not limited thereto. For example, although the base film BF may be made of a copolymer combining polymethyl methacrylate (PMMA) and a special PMMA, a copolymer combining polycarbonate (PC) and PI, a copolymer combining PMMA and PI, or a copolymer combining urethane, the embodiments of the present specification are not limited thereto. Although a thickness t1 of the base film BF may range from about 50 μm to about 200 μm, the embodiments of the present disclosure are not limited thereto.

Although the main bonding layer BPN and the nitrogen reactive bonding layer BPP may each comprise a transparent adhesive, the embodiments of the present disclosure are not limited thereto. For example, although the transparent adhesive may be a transparent resin (OCR) or a transparent adhesive (OCA), the embodiments of the present specification are not limited thereto. Although a thickness t2 of the main bonding layer BPN may range from about 50 μm to about 150 μm, the embodiments of the present disclosure are not limited thereto. Although a thickness t3 of the nitrogen reactive bonding layer BPP may range from about 50 μm to about 150 μm, the embodiments of the present disclosure are not limited thereto.

Although the main bonding layer BPN and the nitrogen reactive bonding layer BPP may each include a silicone-based adhesive or an acrylic-based adhesive, the embodiments of the present disclosure are not limited thereto.

The nitrogen reactive bonding layer BPP may comprise bonds between the nitrogen atoms. For example, the nitrogen reactive bonding layer BPP may comprise at least one of an azo compound, a diazo compound, and a pyrrole and imidazole compound. Chemical Formula 1 below represents an azo compound, Chemical Formula 2 represents a diazo compound, and Chemical Formulas 3 to 6 represent pyrrole and imidazole compounds. In Chemical Formulas 3 to 6, R may be an alkyl group.

R—N═N—R [Chemical Formula 1]

In Chemical Formula 1, R is an alkyl group.

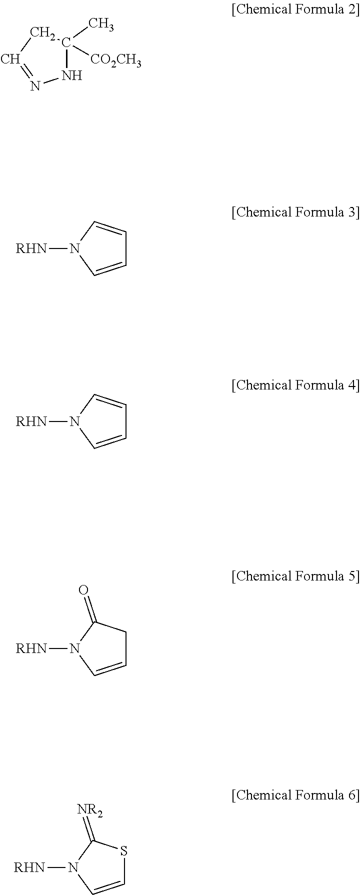

The nitrogen reactive bonding layer BPP of the embodiments according to the present disclosure is not limited to the azo compound, the diazo compound, or the pyrrole and imidazole compound.

When the nitrogen reactive bonding layer BPP includes the azo compound or the diazo compound, each azo compound or diazo compound in the nitrogen reactive bonding layer BPP may have a weight ratio of about 2 wt % or less, but the embodiments of the present specification are not limited thereto. For example, the azo compound or the diazo compound may have a weight ratio of about 2 wt % or less in the total weight of the nitrogen reactive bonding layer BPP. When the nitrogen reactive bonding layer BPP includes the pyrrole and imidazole compound, the pyrrole and imidazole compound in the nitrogen reactive bonding layer BPP may have a weight ratio of about 5 wt % or less, but the embodiments of the present disclosure are not limited thereto. For example, the pyrrole and imidazole compound may have a weight ratio of about 5 wt % or less in the total weight of the nitrogen reactive bonding layer BPP.

The content of nitrogen atoms (N) in the nitrogen reactive bonding layer BPP may be greater than the content of nitrogen atoms (N) in the main bonding layer BPN.

The nitrogen reactive bonding layer BPP may be an ultraviolet reactive bonding layer. For example, the nitrogen reactive bonding layer BPP may react at about 320 nm to about 400 nm to generate nitrogen gas GAS. Although the ultraviolet radiation conditions may be a wavelength range of about 320 nm to about 400 nm and an energy density of smaller than about 5000 mJ/cm² at an output condition of about 430 mW/cm² of a lamp, the embodiments of the present specification are not limited thereto.

The adhesive strength between the nitrogen reactive bonding layer BPP and the tray TRAY may range from about 0.5 kgf/inch to about 2.5 kgf/inch.

As shown in FIG. 10, when the nitrogen reactive bonding layer BPP is irradiated with ultraviolet rays under the above-described radiation conditions, the nitrogen reactive bonding layer BPP′ of the bonding layer BP_2′ may react with ultraviolet rays. The nitrogen reactive bonding layer BPP+ may generate nitrogen gas from the azo compound, the diazo compound, or the pyrrole and imidazole compound. For example, the above-described compounds according to Chemical Formulas 1 to 6 may be transformed into compounds according to Chemical Formulas 7 to 12, respectively.

2R·+N₂ [Chemical Formula 7]

In Chemical Formula 7, R is an alkyl group.

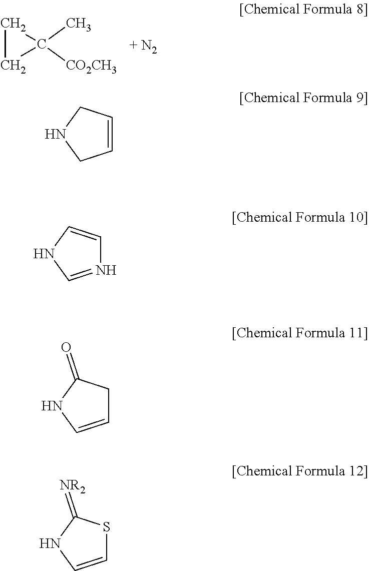

In Chemical Formula 12, R is an alkyl group.

The nitrogen reactive bonding layer BPP′ may react with ultraviolet rays to generate nitrogen gas GAS. The generated nitrogen gas GAS may be positioned between the nitrogen reactive bonding layer BPP′ and the tray TRAY. Since the nitrogen gases GAS are positioned between the nitrogen reactive bonding layer BPP′ and the tray TRAY, the nitrogen reactive bonding layer BPP′ may be spaced a predetermined distance from the tray TRAY or may form the peeling space.

Although the adhesive strength between the nitrogen reactive bonding layer BPP′ and the tray TRAY of FIG. 10 may be smaller than about 0.3 kgf/inch, the embodiments of the present disclosure are not limited thereto.

As shown in FIG. 11, since the nitrogen reactive bonding layer BPP′ is spaced at the predetermined distance from the tray TRAY by the nitrogen gases GAS between the nitrogen reactive bonding layer BPP′ and the tray TRAY to reduce the adhesive strength between the nitrogen reactive bonding layer BPP′ and the tray TRAY, the nitrogen reactive bonding layer BPP′ may be easily peeled from the tray TRAY. In addition, the peeling space may be formed between the nitrogen reactive bonding layer BPP′ and the tray TRAY by nitrogen gases GAS generated from the nitrogen reactive bonding layer BPP′. Therefore, according to one embodiment, the scribing process for forming the peeling space SR described in FIGS. 1 and 2 may not be required. Therefore, since physical damage to the tray TRAY does not occur, the tray TRAY may be reused.

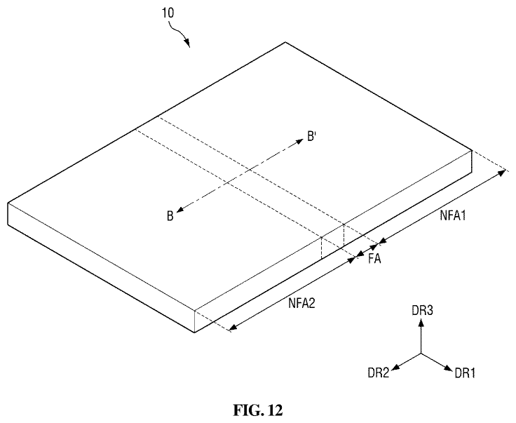

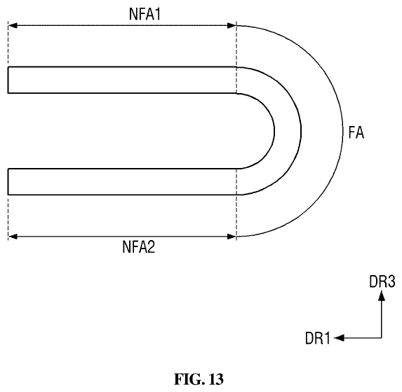

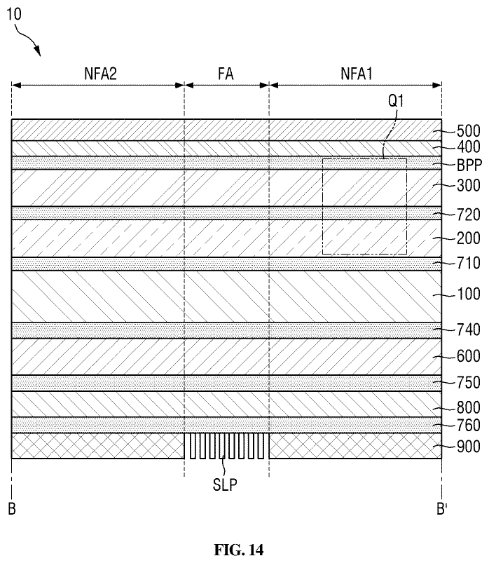

FIG. 12 is a perspective view of a display apparatus according to another embodiment of the present specification. FIG. 13 is a cross-sectional view showing a folded state of the display apparatus according to FIG. 12.

Referring to FIGS. 12 and 13, a display apparatus 10 according to one embodiment may be a foldable display apparatus. FIG. 12 is a view showing an unfolded state of the display apparatus.

The display apparatus 10 may include a folding area FA and an unfolding area near the folding area FA. The folding area FA may extend in a first direction DR1 of the display apparatus 10. The unfolding area may include one or more unfolding areas. For example, the unfolding area may include a first unfolding area NFA1 and a second unfolding area NFA2. The first unfolding area NFA1 may be positioned at one side of the folding area FA in a second direction DR2. The second unfolding area NFA2 may be positioned at the other side of the folding area FA in the second direction DR2. For example, the other side in the second direction DR2 may differ from one side in the second direction DR2. For example, the other side in the second direction DR2 may be opposite to one side in the second direction DR2. The display apparatus 10 may include a display area including a plurality of pixels and a non-display area outside the display area. Although the display area may include portions of the folding area FA and the unfolding areas NFA1 and NFA2 and the non-display area may include other portions of the folding area FA and the unfolding areas NFA1 and NFA2, which are not included in the display area, the embodiments of the present disclosure are not limited thereto.

Referring to FIG. 13, the display apparatus 10 may be folded based on the folding area FA. For example, when the display apparatus 10 is folded, the first unfolding area NFA1 and the second unfolding area NFA2 may be disposed to overlap each other in a thickness direction.

However, the present specification is not limited thereto, and the display apparatus 10 may be a stretchable display apparatus or a bendable display apparatus. In the present specification, the stretchable display apparatus may be referred to as a display apparatus capable of displaying images even when bent or stretched. The foldable display apparatus and the stretchable display apparatus may have higher flexibility than general display apparatuses. A shape of the stretchable display apparatus may be freely changed according to a user's manipulation, for example, by bending or stretching the stretchable display apparatus. For example, when the user holds and pulls an end of the stretchable display apparatus, the stretchable display apparatus may be stretched by the user's force. Alternatively, when the user arranges the stretchable display apparatus on an uneven wall, the stretchable display apparatus may be disposed to be bent along a shape of a surface of the wall. In addition, when the force applied by the user is removed, the stretchable display apparatus may return to an original shape.

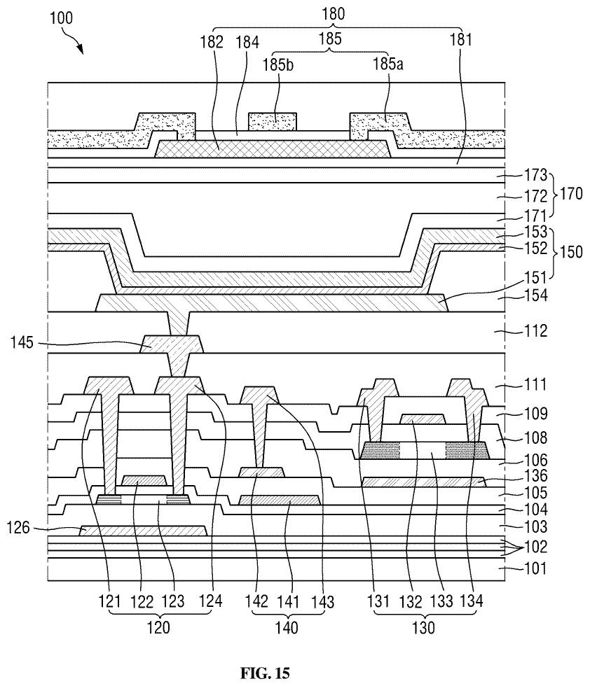

FIG. 14 is a cross-sectional view along line B-B′ in FIG. 12.

Referring to FIG. 14, the display apparatus 10 according to one embodiment of the present specification may include a lower structure and an upper structure on the lower structure.

The lower structure may include a display panel 100, a polarization layer 200, a backplate layer 600, a first plate layer 800, and a second plate layer 900. Although the display panel 100, the polarization layer 200, the backplate layer 600, the first plate layer 800, and the second plate layer 900 may be represented by members, the embodiments of the present specification are not limited thereto.

The display panel 100 may include a plurality of pixels disposed in a display area of a base substrate and driving units disposed in a non-display area around the display area to drive the pixels.

The pixels may include transistors connected to the driving units by control signal lines, and light-emitting elements connected to the transistors.

The transistors may be turned on or off according to control signals applied through the control signal lines to control the amount of a current applied to the light-emitting elements.

The light-emitting elements may emit light with a brightness corresponding to the amount of a current applied through the transistors. Although the light-emitting element may include an organic light-emitting diode, the embodiments of the present disclosure are not limited thereto. For example, the light-emitting element may include an inorganic light-emitting diode, a quantum dot diode, a micro LED diode, or a mini LED diode.

The base substrate may include a flexible substrate. For example, the base substrate may be an insulating plastic substrate of one selected from polyimide, polyethersulfone, polyethylene terephthalate, and polycarbonate, and the embodiments of the present disclosure are not limited thereto. Since the base substrate of the display panel 100 includes a flexible substrate, the display apparatus 10 may be implemented as a foldable, stretchable, or bendable display apparatus, but the embodiments of the present disclosure are not limited thereto.

The backplate layer 600 may be disposed under the display panel 100. The backplate layer 600 may be disposed under the display panel 100 to support the display panel 100. The backplate layer 600 may include a material capable of supporting the display panel 100. For example, although the backplate layer 600 may include polyethylene terephthalate (PET), polyimide (PI), or polycarbonate (PC), the embodiments of the present disclosure are is not limited thereto. The backplate layer 600 can constantly maintain a curvature of the display panel 100 when the display apparatus 10 is folded and suppress wrinkles occurring on an upper surface of the display panel 100.

The polarization layer 200 may be disposed above the display panel 100. The polarization layer 200 may polarize light emitted from the display panel 100 at a polarization angle. The polarization layer 200 may emit light polarized at the polarization angle to the outside. The polarization layer 200 may include a function of blocking the reflection of light excluding the light polarized at the polarization angle among external light.

Plate layers 800 and 900 may be disposed under the backplate layer 600. The plate layers 800 and 900 may include a first plate layer 800 and a second plate layer 900 disposed under the first plate layer 800. The first and second plate layers 800 and 900 may include a metal. For example, although the first and second plate layers 800 and 900 may include stainless steel, the embodiments of the present disclosure are not limited thereto. The second plate layer 900 may include patterns SLP disposed in the folding area FA. The first plate layer 800 may be disposed on the second plate layer 900, thereby preventing the patterns SLP from being visible. For example, the pattern SLP may be disposed to correspond to the folding area FA. The pattern SLP can improve the folding performance of the display apparatus by allowing the second plate layer 900 in the folding area to be easily folded and easily restored to an original state after folding. For example, the patterns SLP may be disposed to be spaced apart from each other at regular intervals. Although the patterns SLP may be opening patterns, the embodiments of the present disclosure are not limited thereto.

The polarization layer 200 may include a first phase retardation layer, a second phase retardation layer disposed on the first phase retardation layer, and a polarization layer disposed on the second phase retardation layer. In FIG. 14, although an example in which the polarization layer 200 and the display panel 100 are separated from each other is shown, the embodiments of the present disclosure are not limited thereto, and the polarization layer 200 may be included in the display panel 100.

The lower structure may further include bonding layers for coupling adjacent members 100, 200, 600, 800, and 900. The bonding layers may include a first bonding layer 710, a second bonding layer 720, a fourth bonding layer 740, a fifth bonding layer 750, and a sixth bonding layer 760.

The first bonding layer 710 may be disposed between the display panel 100 and the polarization layer 200. The first bonding layer 710 may connect or couple the display panel 100 with the polarization layer 200.

The second bonding layer 720 may be disposed between the polarization layer 200 and the cover layer 300. The second bonding layer 720 may connect or couple the polarization layer 200 with the cover layer 300.

The fourth bonding layer 740 may be disposed between the backplate layer 600 and the display panel 100. The fourth bonding layer 740 may connect or couple the backplate layer 600 with the display panel 100.

The fifth bonding layer 750 may be disposed between the backplate layer 600 and the first plate layer 800. The fourth bonding layer 740 may connect or couple the backplate layer 600 with the first plate layer 800.

The sixth bonding layer 760 may be disposed between the first plate layer 800 and the second plate layer 900. The sixth bonding layer 760 may connect or couple the first plate layer 800 with the second plate layer 900.

Although the first bonding layer 710, the second bonding layer 720, the fourth bonding layer 740, the fifth bonding layer 750, and the sixth bonding layer 760 may each include a transparent adhesive, the embodiments of the present disclosure are not limited thereto. For example, although the transparent adhesive may be a transparent resin (OCR) or a transparent adhesive (OCA), the embodiments of the present disclosure are not limited thereto.

The upper structure may include the cover layer 300.

The cover layer 300 may be disposed on the polarization layer 200. Although the cover layer 300 may be made of a glass material including glass or quartz, the embodiments of the present disclosure are not limited thereto. The cover layer 300 may be disposed on the display panel 100 to protect the members (e.g., the lower structure) disposed under the cover layer 300 from the outside. Although the cover layer 300 may be a cover layer formed by chemical reinforcement, the embodiments of the present specification are not limited thereto. Although the cover layer 300 may be a cover window, a window cover, or a cover member, the embodiments of the present disclosure are not limited thereto.

The cover layer 300 can protect the members disposed under the cover layer 300 from the outside, but as described above, since the cover layer 300 is made of a glass material, the cover layer 300 may be damaged by an external force to create glass fragments. The glass fragments may disperse to the outside of the display apparatus 10. According to the embodiment of the present disclosure, to prevent the shattering of the glass fragments due to the damage to the cover layer 300 or increase the durability of the cover layer 300, the display apparatus 10 may further include at least one additional layer on the cover layer 300. For example, the upper structure of the display apparatus 10 may further include a nitrogen reactive bonding layer BPP and a film layer 400.

The film layer 400 may protect the cover layer 300. Although the film layer 400 may be a thin film sheet made of a polymer organic material, the embodiments of the present disclosure are not limited thereto. For example, although the film layer 400 may be made of PI, (poly) norbornene, high heat-resistant PET, an epoxy resin, (poly) urethane, the embodiments of the present specification are not limited thereto. For another example, the film layer 400 may be made of a co-polymer. For example, although the film layer 400 may be made of a copolymer combining polymethyl methacrylate (PMMA) with PMMA, a copolymer combining polycarbonate (PC) with PI, a copolymer combining PMMA with PI, or a copolymer combining urethane, the embodiments of the present specification are not limited thereto. A coating layer 500 may be disposed above the film layer 400.

According to the embodiments according to the present specification, although the display apparatus may further include a coating layer implemented as a surface protection layer on the film layer 400, the embodiments of the present disclosure are not limited thereto.

The nitrogen reactive bonding layer BPP may include a transparent adhesive. For example, although the transparent adhesive may be a transparent resin (OCR) or a transparent adhesive (OCA), the embodiments of the present disclosure are not limited thereto. The nitrogen reactive bonding layer BPP may be disposed between the cover layer 300 and the film layer 400. The nitrogen reactive bonding layer BPP may bond or connect the cover layer 300 to the film layer 400. FIG. 15 is a cross-sectional view of a display panel according to FIG. 14.

Referring to FIG. 15, the display panel 100 may include a substrate 101, a first thin film transistor 120, a second thin film transistor 130, a light emitting part 150, an encapsulation part 170, and a touch part 180.

The substrate 101 may comprise one or more plastic materials. For example, although the substrate 101 may be a multi-substrate including a plurality of plastic materials such as polyimide, the embodiments of the present disclosure are not limited thereto.

The buffer layer 102 may be disposed on the substrate 101. The buffer layer 102 can minimize or delay the diffusion of moisture or oxygen permeating the substrate 101. Although the buffer layer 102 may be formed by alternately stacking silicon nitride (SiNₓ) and silicon oxide (SiOₓ) at least once, the embodiments of the present disclosure are not limited thereto.

A first light blocking layer 126 may be disposed on the buffer layer 102. The first light blocking layer 126 can prevent light from being transmitted through a first semiconductor layer 123 of the first thin film transistor 120. For example, the first semiconductor layer 123 may be disposed to overlap the first light blocking layer 126. Although the first light blocking layer 126 may be formed of a single layer or multiple layers made of any one of molybdenum (Mo), aluminum (Al), chromium (Cr), nickel (Ni), neodymium (Nd), and copper (Cu) or an alloy thereof, the embodiments of the present disclosure are not limited thereto.

A first insulating layer 103 may be disposed on the first light blocking layer 126. The first insulating layer 103 can prevent a short between a component of the first thin film transistor 120 and the first light blocking layer 126. Although the first insulating layer 103 may be made of the same material as the buffer layer 102, the embodiments of the present specification are not limited thereto. For example, although the first insulating layer 103 may be made of an inorganic material, such as silicon nitride (SiNₓ) or silicon oxide (SiOₓ), the embodiments of the present specification are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. Although the first semiconductor layer 123 may include a metal oxide semiconductor, such as indium-gallium-zinc oxide (IGZO), and a silicon-based semiconductor material, such as amorphous silicon or polycrystalline silicon, the embodiments of the present specification are not limited thereto. The first semiconductor layer 123 may include a channel area, a source area, and a drain area.

Since the polycrystalline semiconductor layer has higher mobility than the amorphous semiconductor layer and the oxide semiconductor layer, consumed power can be low, and reliability can be adequate. Therefore, the driving transistor may be formed of the polycrystalline semiconductor layer.

A second insulating layer 104 may be disposed on the first semiconductor layer 123. The second insulating layer 104 may be made of the same material as the first insulating layer 103 and can prevent a short between the first semiconductor layer 123 and another component of the first thin film transistor 120.

A first gate electrode 122 may be disposed on the second insulating layer 104. The first gate electrode 122 may be disposed on the second insulating layer 104 to overlap the channel area of the first semiconductor layer 123. Although the first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, the embodiments of the present specification are not limited thereto. The first gate electrode 122 may be disposed together with gate lines.

A third insulating layer 105 may be disposed on the first gate electrode 122. Although the third insulating layer 105 may be made of the same material as the first insulating layer 103 or the second insulating layer 104, the embodiments of the present disclosure are not limited thereto.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be made of a metal material. For example, although the first source electrode 121 and the first drain electrode 124 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, the embodiments of the present disclosure are not limited thereto.

The first source electrode 121 and the first drain electrode 124 may be disposed together with data lines. For example, although the data line may be made of the same material as the first source electrode 121 and the first drain electrode 124 and formed coplanarly therewith, the embodiments of the present disclosure are not limited thereto.

The storage electrode 140 may be disposed to be spaced apart from the first thin film transistor 120. The storage electrode 140 may include a first storage electrode 141, a second storage electrode 142, and a third storage electrode 143.

Although the first storage electrode 141 may be made of the same material as the first gate electrode 122 and may be formed coplanarly therewith, the embodiments of the present disclosure are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. Although the second storage electrode 142 may be made of the same material as the first storage electrode 141, the embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light blocking layer 136 may be disposed coplanarly with the second storage electrode 142.

The second light blocking layer 136 can prevent light directed to the second semiconductor layer 133 similar to the first light blocking layer 126, thereby extending the lifetime of the second thin film transistor 130. For example, the second semiconductor layer 133 may be disposed to overlap the second light blocking layer 136.

A fourth insulating layer 106 may be disposed on the second light blocking layer 136. Although the fourth insulating layer 106 may be made of the same material as the first insulating layer 103, the second insulating layer 104, or the third insulating layer 105, the embodiments of the present disclosure are not limited thereto.

The second semiconductor layer 133 may be disposed on the fourth insulating layer 106. The second semiconductor layer 133 may include a source area, a drain area, and a channel area between the source area and the drain area.

Although the second semiconductor layer 133 may include a metal oxide semiconductor, such as indium-gallium-zinc oxide (IGZO), and a silicon-based semiconductor material, such as amorphous silicon or polycrystalline silicon, the embodiments of the present disclosure are not limited thereto.

A fifth insulating layer 108 may be disposed on the second semiconductor layer 133. Although the fifth insulating layer 108 may be made of the same material as the first insulating layer 103, the second insulating layer 104, the third insulating layer 105, or the fourth insulating layer 106, the embodiments of the present disclosure are not limited thereto.

A second gate electrode 132 may be disposed on the fifth insulating layer 108.

The second gate electrode 132 may be made of the same material as the first gate electrode 122. For example, although the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, the embodiments of the present disclosure are not limited thereto.

A sixth insulating layer 109 may be disposed on the second gate electrode 132. Although the sixth insulating layer 109 may be made of the same material as the first insulating layer 103, the second insulating layer 104, the third insulating layer 105, the fourth insulating layer 106, or the fifth insulating layer 108, the embodiments of the present disclosure are not limited thereto.

The first source electrode 121, the first drain electrode 124, the third storage electrode 143, the second source electrode 131, and the second drain electrode 134 may be disposed on the sixth insulating layer 109.

Although the third storage electrode 143, the second source electrode 131, and the second drain electrode 134 may be made of the same material as the first source electrode 121 and the first drain electrode 124 and disposed coplanarly therewith, the embodiments of the present disclosure are not limited thereto. For example, although the third storage electrode 143, the second source electrode 131, and the second drain electrode 134 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, the embodiments of the present disclosure are not limited thereto.

Although the first thin film transistor 120 may be a driving transistor, and the second thin film transistor 130 may be a switching transistor, the embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be made of an organic material. For example, although the first protective layer 111 may be made of an organic material containing an acrylic resin, an epoxy resin, a phenolic resin, a polyamide resin, or a polyimide resin, the embodiments of the present disclosure are not limited thereto.

A second protective layer 112 may be disposed on the first protective layer 111. Although the second protective layer 112 may be made of the same material as the first protective layer 111, the embodiments of the present disclosure are not limited thereto.

A connection electrode 145 may be disposed between the first protective layer 111 and the second protective layer 112.

The connection electrode 145 may electrically connect the first thin film transistor 120 with the light emitting part 150. Although the connection electrode 145 may be made of the same material as the first source electrode 121 and the first drain electrode 124, the embodiments of the present disclosure are not limited thereto.

Although the connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, the embodiments of the present disclosure are not limited thereto.

The light emitting part 150 may be disposed on the second protective layer 112. The light emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. Although the anode electrode 151 may be a reflective electrode that reflects light, the embodiments of the present disclosure are not limited thereto. Although the anode electrode 151 may include a metal material with high reflectivity, such as a stacking structure (Ti/Al/Ti) of aluminum (Al) and titanium (Ti), a stacking structure (ITO/Al/ITO) of aluminum (Al) and indium tin oxide (ITO), or an APC alloy, and may be formed of a single layer or multiple layers, the embodiments of the present disclosure are not limited thereto.

The organic layer 152 may be disposed on the anode electrode 151. The organic layer 152 may include one or more light emitting structures (or light emitting elements or elements) stacked on the anode electrode 151 in the order or reverse order of a hole transport layer and an electron transport layer. For example, although the hole transfer layer may include a hole transport layer, a hole injection layer, an electron blocking layer, a p-type charge generation layer, the embodiments of the present disclosure are not limited thereto. For example, although the electron transfer layer may include an electron transport layer, an electron injection layer, a hole blocking layer, an n-type charge generation layer, the embodiments of the present disclosure are not limited thereto. Although the organic layer 152 may be an organic light emitting layer, an inorganic light emitting layer, a quantum dot light emitting layer, a micro light emitting diode, a micro mini light emitting diode, etc., the embodiments of the present disclosure area not limited thereto. For example, the organic layer 152 of the display panel 100 according to one embodiment of the present specification may include the organic light emitting layer. The organic layer 152 may include a red light emitting layer, a green light emitting layer, and a blue light emitting layer. Although the organic layer 152 may be a white light emitting layer, the embodiments of the present disclosure are not limited thereto.

The cathode electrode 153 may be disposed on the organic layer 152. Although the cathode electrode 153 may be a transparent electrode that reflects light, the embodiments of the present disclosure are not limited thereto. For example, although the cathode electrode 153 may include a transparent conductive material, such as indium tin oxide (ITO) or indium zinc oxide (IZO), or a metal that transmits visible light, the embodiments of the present disclosure are not limited thereto.

The bank 154 may be disposed to expose the anode electrode 151. The bank 154 may define an opening (or a light emitting area) of the sub-pixel and may be disposed to cover an edge portion of the anode electrode 151. Each sub-pixel may include a red light emitting area, a green light emitting area, and a blue light emitting area. For example, the sub-pixel may be a pixel, but is not limited by the term. Although the bank 154 may be made of a material containing black pigment, or an organic material such as a benzocyclobutene resin, a polyimide resin, an acrylic resin, or a photosensitive polymer, the embodiments of the present disclosure are not limited thereto. When the bank 154 is made of a material containing black pigment or black dye, it may be a black bank. When the bank 154 is made of a material containing black pigment or black dye, it is possible to block light from the outside or light reflected from the outside, thereby further increasing the luminance of the display apparatus. A spacer may be further disposed on the bank 154. Although the spacer may be made of the same material as the bank 154, the embodiments of the present disclosure are not limited thereto.

The encapsulation part 170 may be disposed on the bank 154 or the light emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, although the first encapsulation layer 171 and the third encapsulation layer 173 may include an inorganic material, and the second encapsulation layer 172 may include an organic material, the embodiments of the present disclosure are not limited thereto.

A buffer layer 181 may be disposed on the encapsulation part 170. For example, the buffer layer 181 may be disposed on the third encapsulation layer 173. Although the buffer layer 181 may be made of the same material as the buffer layer 102, the embodiments of the present specification are not limited thereto. An insulating layer 184 may be disposed on the buffer layer 181. The insulating layer 184 can prevent a short between touch electrodes. Although the insulating layer 184 may be made of silicon oxide (SiOₓ), silicon nitride (SiNₓ), or multiple layers thereof, the embodiments of the present disclosure are not limited thereto. A first touch electrode 185 may be disposed on the insulating layer 184. The first touch electrode 185 may include a la touch electrode 185a extending in a first direction and a 1b touch electrode 185b extending in a second direction that differs from the first direction.

A second touch electrode 182 may be disposed between the buffer layer 181 and the insulating layer 184.

The second touch electrode 182 may be electrically connected to the la touch electrode 185a through a contact hole formed in the insulating layer 184. For example, the la touch electrode 185a and the second touch electrode 182 may extend in the first direction.

The first touch electrode 185 and the second touch electrode 182 may include a metal material. For example, although the first touch electrode 185 and the second touch electrode 182 may be made of titanium (Ti), nickel (Ni), aluminum (Al), or an alloy thereof and may be formed of a triple layer, such as titanium (Ti)/aluminum (Al)/titanium (Ti), the embodiments of the present disclosure are not limited thereto.

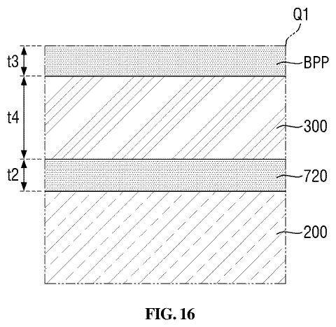

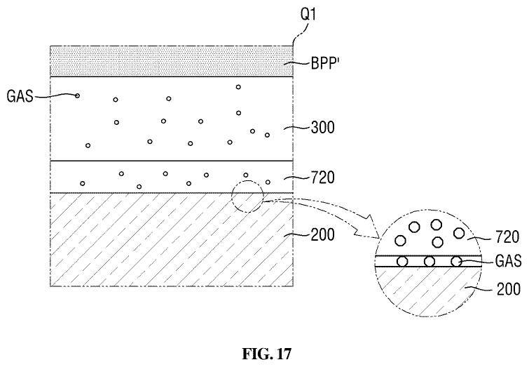

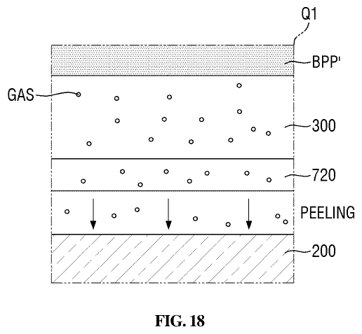

FIG. 16 is an enlarged cross-sectional view of area Q1 in FIG. 14. FIG. 17 is a cross-sectional view showing a case in which ultraviolet rays are radiated to the display apparatus according to FIG. 16. FIG. 18 is a schematic view showing that a second bonding layer is peeled from a polarization layer when ultraviolet rays are radiated according to FIG. 17.

Referring to FIGS. 16 to 18, although the thickness t1 of the film layer 400 may range from about 25 μm to about 100 μm, the embodiments of the present disclosure are not limited thereto. Although the thickness t3 of the nitrogen reactive bonding layer BPP may range from about 10 μm to about 150 μm, the embodiments of the present disclosure are not limited thereto.

Although the thickness t4 of the cover layer 300 may range from about 25 μm to about 100 μm, the embodiments of the present disclosure are not limited thereto.

Although the cover layer 300 may include plastic, the embodiments of the present disclosure are not limited thereto. Although the cover layer 300 may be made of an organic material containing an acrylic resin, an epoxy resin, a phenolic resin, a polyamide resin, or a polyimide resin, the embodiments of the present disclosure are not limited thereto.

Although the second bonding layer 720 and the nitrogen reactive bonding layer BPP may each include a transparent adhesive, the embodiments of the present disclosure are not limited thereto. For example, although the transparent adhesive may be a transparent resin (OCR) or a transparent adhesive (OCA), the embodiments of the present disclosure are not limited thereto.

Although the main bonding layer 720 and the nitrogen reactive bonding layer BPP may each include a silicone-based adhesive or an acrylic-based adhesive, the embodiments of the present disclosure are not limited thereto.

For example, the nitrogen reactive bonding layer BPP may include at least one of an azo compound, a diazo compound, and a pyrrole and imidazole compound.

The azo compound and the diazo compound may each be compounds having a predetermined color, and the pyrrole and imidazole compound may be a transparent compound. The nitrogen reactive bonding layer BPP may be positioned in an emission direction of the display panel 100. Therefore, the nitrogen reactive bonding layer BPP should satisfy transmittance conditions. In addition, since the nitrogen reactive bonding layer BPP is positioned in the emission direction, it is preferable to minimize the haze scattered by the azo compound, the diazo compound, or the pyrrole and imidazole compound in the nitrogen reactive bonding layer BPP. For example, although the transmittance conditions of the nitrogen reactive bonding layer BPP may be about 98% or more and haze conditions may be about 1% or less, the embodiments of the present disclosure are not limited thereto.

Since the pyrrole and imidazole compound is a transparent compound, the transmittance (%) of the nitrogen reactive bonding layer BPP including the pyrrole and imidazole compound may be 100 regardless of the content (wt %) of the pyrrole and imidazole compound. In addition, it was confirmed that even when the content (wt %) of the pyrrole and imidazole compound in the nitrogen reactive bonding layer BPP was 0.5 wt %, 1.0 wt %, 2.0 wt %, and 5.0 wt %, the haze (%) ranged from about 0.2% to about 0.3%.

Since the azo compound or the diazo compound is an opaque compound having a color, the transmittance and haze may increase in proportion to the content (wt %) of the azo compound or the diazo compound. For example, it was confirmed that when the content (wt %) of the azo compound or the diazo compound in the nitrogen reactive bonding layer BPP was 0.25 wt %, the transmittance (%) exceeded 99% and the haze (%) was 0.3%. For example, it was confirmed that when the content (wt %) of the azo compound or the diazo compound in the nitrogen reactive bonding layer BPP was 0.5 wt %, the transmittance (%) was 98% and the haze (%) was 0.5%. For example, it was confirmed that when the content (wt %) of the azo compound or the diazo compound in the nitrogen reactive bonding layer BPP was 1 wt %, the transmittance (%) was 90% and the haze (%) was 0.7%. For example, it was confirmed that when the content (wt %) of the azo compound or the diazo compound in the nitrogen reactive bonding layer BPP was 2 wt %, the transmittance (%) was 87.1% and the haze (%) was 1.2%. Therefore, in the case of the display apparatus 10 according to the embodiment, to satisfy the transmittance conditions or the haze conditions of the nitrogen reactive bonding layer BPP, the content (wt %) of the azo compound or the diazo compound in the nitrogen reactive bonding layer BPP may be about 2 wt % or less.

The content of nitrogen atom (N) in the nitrogen reactive bonding layer BPP may be greater than the content of nitrogen atom (N) in the second bonding layer 720.

The nitrogen reactive bonding layer BPP may be an ultraviolet reactive bonding layer. For example, the nitrogen reactive bonding layer BPP may react at about 320 nm to about 400 nm to generate nitrogen gas GAS. Although the ultraviolet radiation conditions may be a wavelength range of about 320 nm to about 400 nm and an energy density of smaller than about 5000 mJ/cm² at an output condition of about 430 mW/cm² of a lamp, the embodiments of the present disclosure are not limited thereto.

Hereinafter, a first experiment regarding the ultraviolet radiation conditions for the nitrogen reactive bonding layer BPP will be described. A width of a sample, a material of an adhesive, or a thickness of the adhesive of the first experiment does not limit the contents of the present disclosure. A width of a first sample of the first experiment was formed to be 5 cm. The first sample was composed of glass, a first adhesive (the same material as the second bonding layer 720 of FIG. 16) on the glass, a polymer film (the same material as the cover layer 300 of FIG. 16) on the adhesive, a second adhesive (the same material as the nitrogen reactive bonding layer BPP of FIG. 16) on the polymer film, and a base film (the same material as the film layer 400 of FIG. 14) on the second adhesive. The first adhesive was a silicone-based adhesive and was formed to have the thickness of about 10 μm. The polymer film was a polyimide and was formed to have the thickness of about 50 μm. Before ultraviolet radiation, the adhesive strength between the glass and the first adhesive was measured to be about 1.23 kgf/inch. After primary ultraviolet radiation, it could be confirmed that bubbles were generated on the entire surface of the first sample, and the adhesive strength between the glass and the first adhesive was measured to be 0.41 kgf/inch, which was reduced by about 67% compared to before the ultraviolet radiation. After secondary ultraviolet radiation, the adhesive strength between the glass and the first adhesive was measured to be about 0.31 kgf/inch, and after tertiary ultraviolet radiation, the adhesive strength between the glass and the first adhesive was measured to be about 0.32 kgf/inch. It was confirmed that the adhesive strength between the glass and the first adhesive after the secondary ultraviolet radiation did not significantly differ from the adhesive strength between the glass and the first adhesive after the tertiary ultraviolet radiation. Therefore, as the result of the first experiment, it was confirmed that the effective number of ultraviolet radiations to weaken the adhesive strength between the glass and the first adhesive was 2, but the embodiments of the present disclosure are not limited thereto. In addition, it was confirmed that when the first sample was irradiated with ultraviolet rays, nitrogen gas (or bubbles) was generated from the second adhesive, thereby reducing the adhesive strength between the glass and the first adhesive. In the first experiment, for convenience of experiment, the first sample adopted glass instead of the polarization layer 200 of FIG. 16, and thus there may be a difference in the adhesive strength between the glass and the first adhesive and between the polarization layer 200 and the first adhesive before and after ultraviolet radiation. However, through the result of the first experiment, it could be confirmed that even in the case of a display apparatus 10 according to a second embodiment, the nitrogen reactive bonding layer BPP was irradiated with ultraviolet rays (significantly up to twice) to weaken the adhesive strength between the polarization layer 200 and the second bonding layer 720.

The adhesive strength between the second bonding layer 720 and the polarization layer 200 may be about 0.8 kgf/inch or more. For example, although the second bonding layer 720 may include an acryl-based adhesive, the embodiments of the present disclosure are not limited thereto.

Hereinafter, a second experiment regarding the adhesive strength between glass and the first adhesive according to the material or thickness of the first adhesive of the first sample, a second sample, a third sample, and a fourth sample during ultraviolet radiation will be described. Widths of samples, a material of an adhesive, or a thickness of the adhesive of the second experiment does not limit the contents of the present disclosure. The width of each sample is 5 cm. The first sample was composed of glass, a first adhesive (the same material as the second bonding layer 720 of FIG. 16) on the glass, a polymer film (the same material as the cover layer 300 of FIG. 16) on the adhesive, a second adhesive (the same material as the nitrogen reactive bonding layer BPP of FIG. 16) on the polymer film, and a base film (the same material as the film layer 400 of FIG. 14) on the second adhesive. The first adhesive was a silicone-based adhesive and was formed to have the thickness of about 10 μm. The polymer film was a polyimide and was formed to have the thickness of about 50 μm. The second sample differs from the first sample in that the first adhesive is an acryl-based adhesive and has the thickness of about 15 μm, and the third sample differs from the first sample in that the first adhesive is a silicon-based adhesive that is the same as that of the first sample but has the thickness of about 150 μm. The fourth sample differs from the third sample in that it is an acryl-based adhesive.

In the case of the first sample, the adhesive strength between the glass and the first adhesive was measured to be about 1.23 kgf/inch before ultraviolet radiation. After primary ultraviolet radiation, it could be confirmed that bubbles were generated on the entire surface of the first sample, and the adhesive strength between the glass and the first adhesive was measured to be 0.41 kgf/inch, which was reduced by about 67% compared to before the ultraviolet radiation.

In the case of the second sample, before ultraviolet radiation, the adhesive strength between the glass and the first adhesive was measured to be about 1.19 kgf/inch. After primary ultraviolet radiation, it could be confirmed that bubbles were generated on the entire surface of the first sample, and the adhesive strength between the glass and the first adhesive was measured to be 0.54 kgf/inch, which was reduced by about 55% compared to before the ultraviolet radiation.

In the case of the third sample, the adhesive strength between the glass and the first adhesive before ultraviolet radiation was measured to be about 3.94 kgf/inch but after the primary ultraviolet radiation, the adhesive strength between the glass and the first adhesive was measured to be about 3.59 kgf/inch, which was reduced by about 9% compared to before ultraviolet radiation.

In the case of the fourth sample, the adhesive strength between the glass and the first adhesive before ultraviolet radiation was measured to be about 2.45 kgf/inch but after the primary ultraviolet radiation, the adhesive strength between the glass and the first adhesive was measured to be about 2.31 kgf/inch, which was reduced by about 6% compared to before ultraviolet radiation.

As the result of the second experiment, it was confirmed that when the first adhesive was a silicon-based adhesive, the adhesive strength was reduced at a greater rate after ultraviolet radiation compared to when the first adhesive was an acryl-based adhesive. This is because the silicon-based adhesive has a free volume fraction compared to the acryl-based adhesive. The free volume fraction may be an empty space or free volume portion. Therefore, since the bubbles (or nitrogen gas) generated from the second adhesive may pass through the second adhesive that is the silicon-based adhesive better than the first adhesive that is the acryl-based adhesive, when the first adhesive is the silicon-based adhesive, the adhesive strength may be reduced at a greater rate after ultraviolet radiation compared to when the first adhesive is the acryl-based adhesive.

In addition, it could be confirmed that the smaller the thickness of the first adhesive, the greater the adhesive strength between the glass and the first adhesive is reduced after ultraviolet radiation. That is, as the thickness of the first adhesive is smaller, a path of the bubbles (or nitrogen gas) generated from the second adhesive (or the nitrogen reactive bonding layer) reaching the interface between the first adhesive and the glass is shorter when ultraviolet is radiated, and thus more bubbles (or nitrogen gas) may be present at the interface between the first adhesive and the glass, thereby weakening the adhesive strength between the first adhesive and the glass. For example, it was confirmed that when the thickness of the first adhesive ranges from about 10 μm to about 15 μm, the adhesive strength with the glass was greatly reduced after ultraviolet radiation.

In the second experiment, for convenience of experiment, each of the first sample, the second sample, the third sample, and the fourth sample adopted glass instead of the polarization layer 200 of FIG. 16, and thus there may be a difference in the adhesive strength between the glass and the first adhesive and between the polarization layer 200 and the first adhesive before and after ultraviolet radiation. Through the result of the second experiment, it could be confirmed that even in the case of the display apparatus 10 according to the second embodiment, as the thickness of the second bonding layer 720 between the polarization layer 200 and the cover layer 300 was smaller, the adhesive strength between the polarization layer 200 and the second bonding layer 720 could be weakened.

As shown in FIG. 17, when the nitrogen reactive bonding layer BPP is irradiated with ultraviolet rays under the above-described radiation conditions, the nitrogen reactive bonding layer BPP′ may react with ultraviolet rays. As confirmed from the results of the first and second experiments, the nitrogen reactive bonding layer BPP′ may react with ultraviolet rays to generate nitrogen gas GAS. For example, although the ultraviolet rays may be radiated once or twice, the embodiments of the present disclosure are not limited thereto. The generated nitrogen gas GAS may be positioned between the second bonding layer 720 and the polarization layer 200. Since the nitrogen gases GAS are positioned between the second bonding layer 720 and the polarization layer 200, the second bonding layer 720 may be spaced a predetermined distance from the polarization layer 200 or may form a peeling space.

The adhesive strength between the second bonding layer 720 and the polarization layer 200 of FIG. 17 may be smaller than about 0.5 kgf/inch. For example, although the second bonding layer 720 may be an acryl-based adhesive and the thickness thereof may be about 15 μm, the embodiments of the present disclosure are not limited thereto.

As shown in FIGS. 17 and 18, since the second bonding layer 720 is spaced the predetermined distance from the polarization layer 200 due to nitrogen gases GAS between the second bonding layer 720 and the polarization layer 200 to reduce the adhesive strength between the second bonding layer 720 and the polarization layer 200, the second bonding layer 720 may be easily peeled off from the polarization layer 200. In addition, a peeling space may be formed between the second bonding layer 720 and the polarization layer 200 by the nitrogen gases GAS generated from the nitrogen reactive bonding layer BPP′. Therefore, according to another embodiment, the scribing process for forming the peeling space SR described above in FIGS. 1 and 2 may not be required. Therefore, since physical damage to the polarization layer 200 does not occur, the polarization layer 200 may be reused.

In addition, according to the display apparatus 10 according to the second embodiment, as described above, to peel the second bonding layer 720 from the polarization layer 200, the nitrogen reactive bonding layer BPP that reacts with ultraviolet rays may be applied, thereby preventing the nitrogen reactive bonding layer BPP from being unintentionally deformed (BPP−>BPP′) under high temperature reliability evaluation conditions of the display apparatus 10. For example, although the display apparatus 10 may be a display apparatus that requires high reliability, such as a navigation display apparatus, the embodiments of the present specification are not limited thereto. For example, the high temperature reliability evaluation conditions of the display apparatus 10 may include haze reliability evaluation, yellow index evaluation, and single product reliability evaluation, and the single product reliability evaluation may include single product reliability evaluation at high temperatures and single product reliability evaluation at high temperature and high humidity. During the haze reliability evaluation, the display apparatus 10 may be exposed to an environment of about 105° C. and 500 hours, during the yellow index evaluation, the display apparatus 10 may be exposed to an environment of about 105° C. and 500 hours, during the high temperature reliability evaluation, the display apparatus 10 may be exposed to an environment of about 105° C. and 500 hours, and during the high temperature and high humidity reliability evaluation, the display apparatus 10 may be exposed to an environment of about 85° C., 500 hours, and transmittance of 80%. For example, when the nitrogen reactive bonding layer BPP is a heat emission nitrogen reactive bonding layer that generates nitrogen gas during heat emission, the nitrogen reactive bonding layer may unintentionally generate nitrogen gas during the high temperature reliability evaluation of the display apparatus 10, thereby causing defects in the display apparatus 10. However, in the case of the display apparatus 10 according to the second embodiment, since the nitrogen reactive bonding layer BPP that reacts with ultraviolet rays is applied, there is an advantage that defects in the display apparatus 10 that may occur during the high temperature reliability evaluation can be prevented.

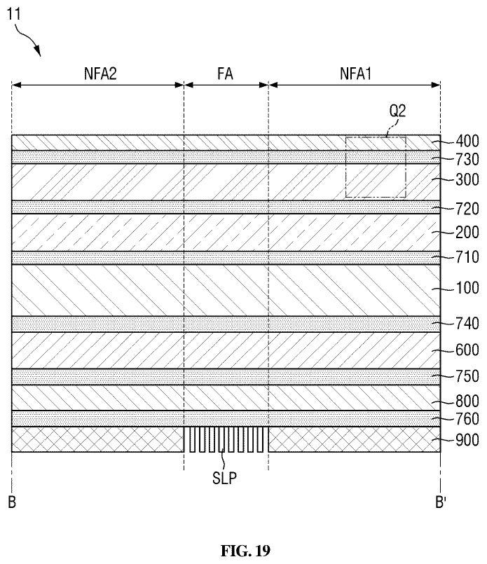

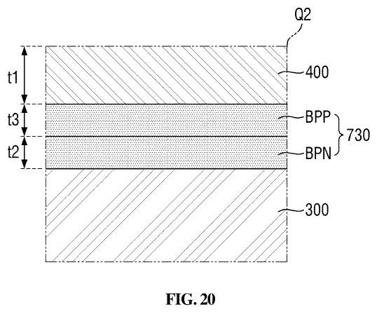

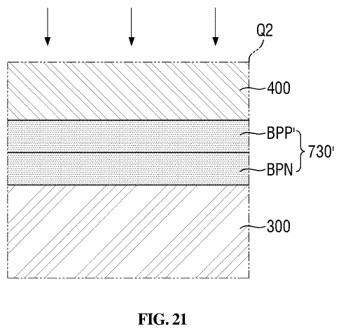

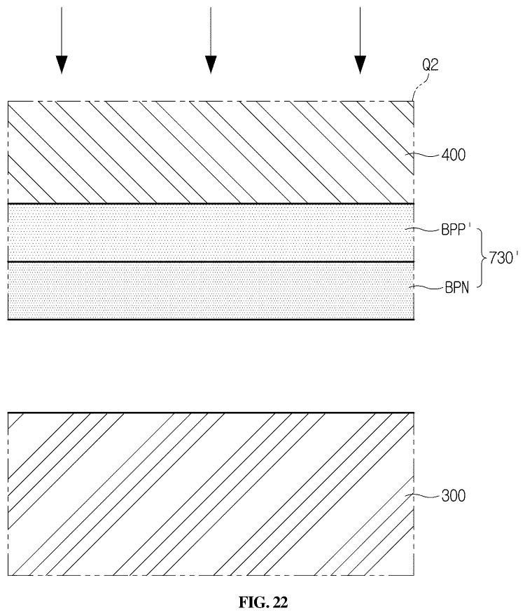

FIG. 19 is a cross-sectional view of a display apparatus according to another embodiment of the present disclosure. FIG. 20 is an enlarged cross-sectional view of area Q2 in FIG. 19. FIG. 21 is a cross-sectional view showing a case in which ultraviolet rays are radiated to the display apparatus according to FIG. 20. FIG. 22 is a schematic view showing that a third bonding layer is peeled from a cover layer when ultraviolet rays are radiated according to FIG. 21.

Referring to FIGS. 19 to 22, an upper structure of the display apparatus 11 according to another embodiment may have a third bonding layer 730 disposed between the cover layer 300 and the film layer 400. The remaining components are substantially the same as those described in FIGS. 14, and 16 to 18 and thus may be denoted by the same reference numerals, and overlapping contents thereof may be omitted or simplified.

The third bonding layer 730 may include a main bonding layer BPN, and a nitrogen reactive bonding layer BPP on the main bonding layer BPN. Although the thickness t1 of the film layer 400 may range from about 25 μm to about 100 μm, the embodiments of the present disclosure are not limited thereto. Although the thickness t2 of the main bonding layer BPN may range from about 10 μm to about 150 μm, the embodiments of the present disclosure are not limited thereto. Although a thickness t3 of the nitrogen reactive bonding layer BPP may range from about 10 μm to about 150 μm, the embodiments of the present disclosure are not limited thereto.

The bonding layer BP_2 of FIG. 9 may have the main bonding layer BPN and the nitrogen reactive bonding layer BPP disposed above and under the base film BF, respectively. The third bonding layer 730 according to FIG. 20 may have the main bonding layer BPN and the nitrogen reactive bonding layer BPP disposed or stacked as a double layer.

Although the main bonding layer BPN and the nitrogen reactive bonding layer BPP may each include a transparent adhesive, the embodiments of the present disclosure are not limited thereto. For example, although the transparent adhesive may be a transparent resin (OCR) or a transparent adhesive (OCA), the embodiments of the present disclosure are not limited thereto.

Although the main bonding layer BPN and the nitrogen reactive bonding layer BPP may each include a silicone-based adhesive or an acrylic-based adhesive, the embodiments of the present disclosure are not limited thereto.

For example, the nitrogen reactive bonding layer BPP may include at least one of an azo compound, a diazo compound, and a pyrrole and imidazole compound.

When the nitrogen reactive bonding layer BPP includes an azo compound or a diazo compound, each azo compound or diazo compound in the nitrogen reactive bonding layer BPP may have a weight ratio of about 2 wt % or less, but the embodiments of the present disclosure are not limited thereto. For example, the azo compound or the diazo compound may have a weight ratio of about 2 wt % or less in the total weight of the nitrogen reactive bonding layer BPP. When the nitrogen reactive bonding layer BPP includes the pyrrole and imidazole compound, the pyrrole and imidazole compound in the nitrogen reactive bonding layer BPP may have a weight ratio of about 5 wt % or less. For example, the pyrrole and imidazole compound may have a weight ratio of about 5 wt % or less in the total weight of the nitrogen reactive bonding layer BPP.

The content of nitrogen atom (N) in the nitrogen reactive bonding layer BPP may be greater than the content of nitrogen atom (N) in the main bonding layer BPN.

The nitrogen reactive bonding layer BPP may be an ultraviolet reactive bonding layer. For example, the nitrogen reactive bonding layer BPP may react at about 320 nm to about 400 nm to generate nitrogen gas GAS. Although the ultraviolet radiation conditions may be a wavelength range of about 320 nm to about 400 nm and an energy density of smaller than about 5000 mJ/cm² at an output condition of about 430 mW/cm² of a lamp, the embodiments of the present disclosure are not limited thereto.

The adhesive strength between the main bonding layer BPN and the cover layer 300 may range from about 1 kgf/inch to about 4 kgf/inch.

The results of the first and second experiments described in the second embodiment may also be applied to a third embodiment. The result of the first experiment is that the effective number of ultraviolet radiations to weaken the adhesive strength between the glass and the first adhesive is two, and when the first sample is irradiated with the ultraviolet rays, nitrogen gas (or bubbles) may be generated from the second adhesive, thereby reducing the adhesive strength between the glass and the first adhesive. The result of the second experiment is that when the first adhesive is a silicon-based adhesive, the adhesive strength is reduced at a greater rate after ultraviolet radiation compared to when the first adhesive is an acryl-based adhesive, and the adhesive strength between the glass and the first adhesive is greatly reduced after ultraviolet radiation as the thickness of the first adhesive is smaller.

As shown in FIGS. 21 and 22, when the nitrogen reactive bonding layer BPP is radiated with ultraviolet rays under the above-described radiation conditions, the nitrogen reactive bonding layer BPP′ of a third bonding layer 730′ may react with ultraviolet rays. The nitrogen reactive bonding layer BPP′ may react with ultraviolet rays to generate nitrogen gas GAS. The generated nitrogen gas GAS may be positioned between the main bonding layer BPN and the cover layer 300. Since the nitrogen gases GAS are positioned between the main bonding layer BPN and the cover layer 300, the main bonding layer BPN may be spaced a predetermined distance from the cover layer 300 or may form a peeling space.

The adhesive strength between the main bonding layer BPN and the cover layer 300 may be smaller than about 0.3 kgf/inch.

Since the main bonding layer BPN is spaced the predetermined distance from the cover layer 300 due to the nitrogen gases GAS between the main bonding layer BPN and the cover layer 300 to weaken the adhesive strength between the main bonding layer BPN and the cover layer 300, the main bonding layer BPN may be easily peeled from the cover layer 300. In addition, the peeling space may be formed between the main bonding layer BPN and the cover layer 300 by the nitrogen gases GAS generated from the nitrogen reactive bonding layer BPP′. Therefore, according to another embodiment, the scribing process for forming the peeling space SR described above in FIGS. 1 and 2 may not be required. Therefore, since physical damage to the cover layer 300 does not occur, the cover layer 300 may be reused.

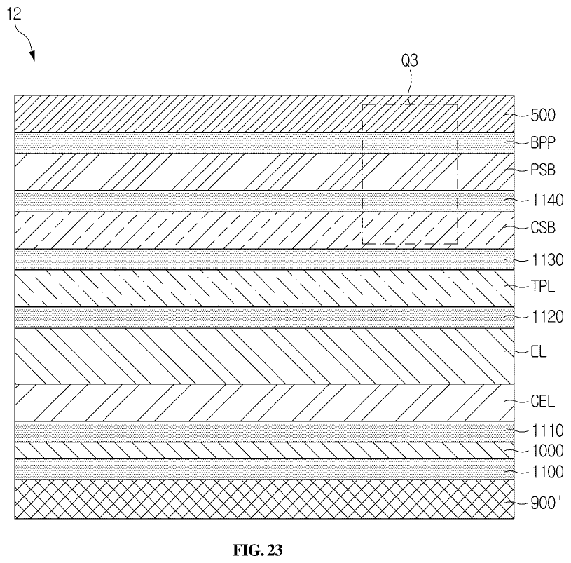

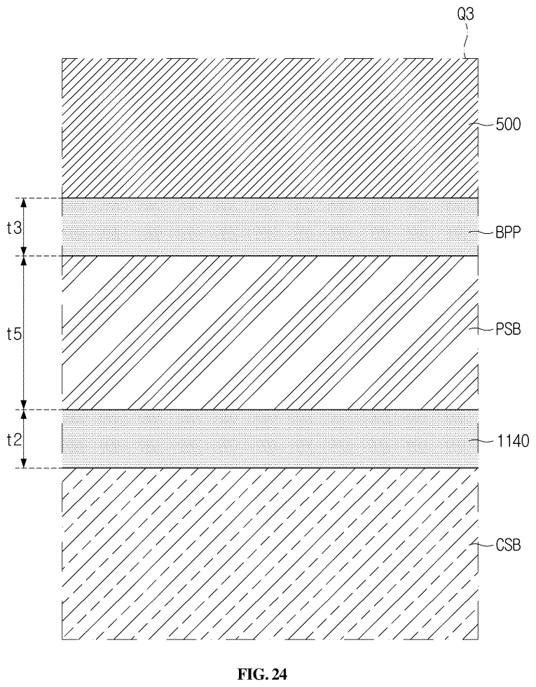

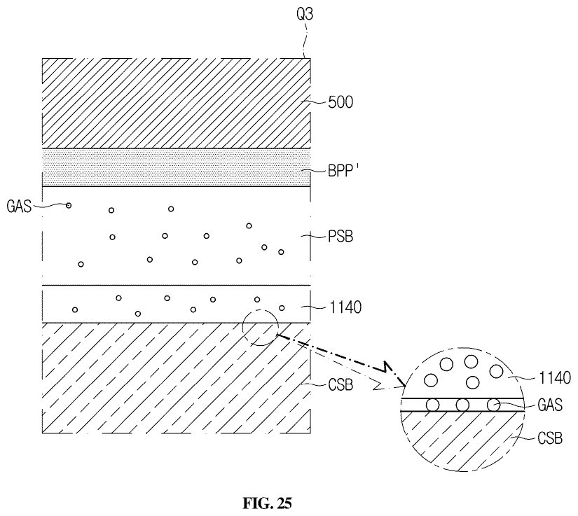

FIG. 23 is a cross-sectional view of a display apparatus according to still another embodiment of the present disclosure. FIG. 24 is an enlarged cross-sectional view of area Q3 in FIG. 23. FIG. 25 is a cross-sectional view showing a case in which ultraviolet rays are radiated to the display apparatus according to FIG. 24.

Referring to FIGS. 23 to 25, a display apparatus 12 according to still another embodiment may be implemented as a stretchable display apparatus.

The display apparatus 12 may include a plate layer 900′, a lower stretchable substrate 1000, a circuit element layer CEL, a light emitting element layer EL, an upper stretchable board TPL, a first stretchable board CSB, a protective stretchable board PSB, a nitrogen reactive bonding layer BPP, and a coating layer 500.

Although the plate layer 900′ may include the same material as the first plate layer 800 or the second plate layer 900 described in FIG. 14, the embodiments of the present disclosure are not limited thereto.

The lower stretchable substrate 1000 may be disposed on the plate layer 900′. The lower stretchable substrate 1000 is a flexible substrate and may be made of a bendable or stretchable insulating material. For example, the lower stretchable substrate 1000 may be made of an elastic polymer such as silicone rubber (e.g., polydimethylsiloxane (PDMS)), polyurethane (PU), or polytetrafluoroethylene (PTFE), and thus may have flexible properties. However, the embodiments according to the present disclosure are not limited thereto.

A first bonding layer 1100 may be disposed between the plate layer 900′ and the lower stretchable substrate 1000. The plate layer 900′ and the lower stretchable substrate 1000 may be bonded through the first bonding layer 1100.

The circuit element layer CEL may be disposed on the lower stretchable substrate 1000. The circuit element layer CEL may include the substrate described in FIG. 15, and at least one thin film transistor. The transistors may be turned on or off according to control signals applied through control signal lines to adjust the amount of a current applied to the light emitting element layer EL.

The first bonding layer 1110 may be disposed between the circuit element layer CEL and the lower stretchable substrate 1000. The circuit element layer CEL and the lower stretchable substrate 1000 may be bonded through the first bonding layer 1110.

The light emitting element layer EL may be disposed on the circuit element layer CEL. The light emitting element layer EL may include at least one light emitting element. The light emitting element may emit light with a brightness corresponding to the amount of a current applied through the transistor. Although the light emitting element may include an organic light emitting diode, the embodiments of the present disclosure are not limited thereto. For example, although the light emitting element may include an inorganic light emitting diode, a quantum dot diode, a micro LED diode, a mini LED diode, the embodiments of the present specification are not limited thereto.

The upper stretchable substrate TPL may be disposed on the light emitting element layer EL. The upper stretchable substrate TPL is, for example, a flexible substrate and may be made of a bendable or stretchable insulating material. For example, the upper stretchable substrate TPL may be made of an elastic polymer such as silicone rubber (e.g., polydimethylsiloxane (PDMS)), polyurethane (PU), or polytetrafluoroethylene (PTFE), and thus may have flexible properties. However, the embodiments according to the present specification are not limited thereto.

The upper stretchable substrate TPL may further include a touch part. For example, although the upper stretchable substrate TPL may be a touch panel or a touch member including the touch part, the embodiments of the present specification are not limited thereto. The touch part may sense a user's touch in a self-capacitance method or a mutual capacitance method. The touch part may include a plurality of touch electrodes, and the plurality of touch electrodes may form a mutual capacitance or a self-capacitance to detect the touch of an object or a person.

A second bonding layer 1120 may be disposed between the light emitting element layer EL and the upper stretchable substrate TPL. The light emitting element layer EL and the upper stretchable substrate TPL may be bonded through the second bonding layer 1120.

The first stretchable board CSB may be disposed on the upper stretchable substrate TPL. For example, the first stretchable board CSB may be made of an elastic polymer such as silicone rubber (e.g., polydimethylsiloxane (PDMS)), polyurethane (PU), or polytetrafluoroethylene (PTFE), and thus may have flexible properties. However, the embodiments according to the present specification are not limited thereto.

A third bonding layer 1130 may be disposed between the upper stretchable substrate TPL and the first stretchable board CSB. The upper stretchable substrate TPL and the first stretchable board CSB may be bonded through the third bonding layer 1130.

The protective stretchable board PSB may be disposed on the first stretchable board CSB. For example, the protective stretchable board PSB may be made of an elastic polymer such as silicone rubber (e.g., polydimethylsiloxane (PDMS)), polyurethane (PU), or polytetrafluoroethylene (PTFE), and thus may have flexible properties. However, the embodiments according to the present specification are not limited thereto. Although the free volume fraction of the protective stretchable board PSB may be about 50 or more, the embodiments of the present specification are not limited thereto. A fourth bonding layer 1140 may be disposed between the first stretchable board CSB and the protective stretchable board PSB. The fourth bonding layer 1140 may connect or couple the first stretchable board CSB and the protective stretchable board PSB.

The nitrogen reactive bonding layer BPP may be disposed on the protective stretchable board PSB. The coating layer 500 may be disposed on the nitrogen reactive bonding layer BPP. The coating layer 500 may be formed by being coated on the upper surface of the nitrogen reactive bonding layer BPP. Since the coating layer 500 allows a front surface of the cover layer 300 to perform a touch function, the coating layer 500 can be implemented as a surface protection layer having more reinforced strength. When the coating layer 500 is formed as the surface protection layer, the coating layer 500 may be made of a resin with relatively high hardness when cured, such as an acrylic resin, an epoxy resin, or a silicon-based compound, but the embodiments of the present disclosure are not limited thereto. In addition, the coating layer 500 may be configured to be assigned an anti-finger (AF) or anti-reflective (AR) function as needed. The coating layer 500 may be implemented by synthesizing the resin having such a function or implemented by forming various patterns, for example, a pattern such as moth eye. Although the coating layer 500 may be a hard coating layer, the embodiments of the present disclosure are not limited thereto.

Although the first bonding layer 1110, the second bonding layer 1120, the third bonding layer 1130, the fourth bonding layer 1140, and the nitrogen reactive bonding layer BPP may each include a transparent adhesive, the embodiments of the present specification are not limited thereto. For example, although the transparent adhesive may be a transparent resin (OCR) or a transparent adhesive (OCA), the embodiments of the present disclosure are not limited thereto.

Although the thickness t2 of the fourth bonding layer 1140 may, for example, range from about 10 μm to about 150 μm, the embodiments of the present specification are not limited thereto. Although a thickness t3 of the nitrogen reactive bonding layer BPP may range from about 10 μm to about 150 μm, the embodiments of the present disclosure are not limited thereto. Although the thickness t5 of the second stretchable board PSB may range from about 5 μm to about 500 μm, the embodiments of the present disclosure are not limited thereto.

The adhesive strength between the fourth bonding layer 1140 and the first stretchable board CSB may range from about 1 kgf/inch to about 3 kgf/inch.

Hereinafter, a third experiment regarding the adhesive strength between the glass and the first adhesive when the fifth sample is irradiated with ultraviolet rays will be described. The material of the adhesive, the thickness of the adhesive, or the ultraviolet radiation conditions of the third experiment do not limit the contents of the present specification. The fifth sample was composed of glass, a first adhesive (the same material as the second bonding layer 1140 of FIG. 24) on the glass, a porous film (PDMS) (the same material as the protective stretchable board PSB of FIG. 24) on the first adhesive, a second adhesive (the same material as the nitrogen reactive bonding layer BPP of FIG. 24) on the porous film, and a base film (the same material as the coating layer 500 of FIG. 24) on the second adhesive. The first adhesive may have the thickness of about 10 μm. The porous film (PDMS) may have the thickness of about 350 μm. The fifth sample may be irradiated with ultraviolet rays. Although the ultraviolet radiation conditions may be a wavelength range of about 365 nm and an energy density of smaller than about 5000 mJ/cm² at an output condition of about 430 mW/cm² of a lamp, the embodiments of the present disclosure are not limited thereto. Although the ultraviolet rays may be radiated once or twice, the embodiments of the present disclosure are not limited thereto.

It could be confirmed that when the fifth sample was irradiated with ultraviolet rays, bubbles were generated on the entire surface of the fifth sample. In addition, the first adhesive could be easily peeled off from the glass. As the result of the third experiment, it was confirmed that since the porous film (PDMS) had the free volume fraction of about 50 or more even when the porous film (PDMS) had the thickness of about 350 μm, bubbles (or nitrogen gas) generated from the second adhesive easily passed through the porous film (PDMS) and were positioned at the interface between the first adhesive and the glass to easily peel the first adhesive from the glass. Since the fifth sample adopts glass instead of the first stretchable board CSB of FIGS. 23 and 24, there may be a difference in the adhesive strength between the glass and the first adhesive and between the first stretchable board CSB and the first adhesive before and after ultraviolet radiation. However, through the result of the third experiment, it could be confirmed that even in the case of the display apparatus 12 according to the second embodiment, the nitrogen reactive bonding layer BPP was irradiated with ultraviolet rays to weaken the adhesive strength between the first stretchable board CSB and the fourth bonding layer 740.

As shown in FIG. 25, when the nitrogen reactive bonding layer BPP is irradiated with ultraviolet rays under the above-described radiation conditions, the nitrogen reactive bonding layer BPP′ may react with ultraviolet rays. The nitrogen reactive bonding layer BPP′ may react with ultraviolet rays to generate nitrogen gas GAS. The generated nitrogen gas GAS may be positioned between the fourth bonding layer 1140 and the first stretchable board CSB. Since the nitrogen gases GAS are positioned between the fourth bonding layer 1140 and the first stretchable board CSB, the fourth bonding layer 1140 may be spaced a predetermined distance from the first stretchable board CSB or may form the peeling space.

The adhesive strength between the fourth bonding layer 1140 and the first stretchable board CSB of FIG. 25 may be smaller than about 0.3 kgf/inch.

As shown in FIG. 25, since the fourth bonding layer 1140 is spaced the predetermined distance from the first stretchable board CSB by the nitrogen gases GAS between fourth bonding layer 1140 and the first stretchable board CSB to reduce the adhesive strength between fourth bonding layer 1140 and the first stretchable board CSB, fourth bonding layer 1140 may be easily peeled from the first stretchable board CSB. In addition, the peeling space may be formed between fourth bonding layer 1140 and the first stretchable board CSB by the nitrogen gases GAS generated from the nitrogen reactive bonding layer BPP′. Therefore, according to another embodiment, the scribing process for forming the peeling space SR described above in FIGS. 1 and 2 may not be required. Therefore, physical damage to the first stretchable board CSB may not occur.

The display apparatus according to various embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation system, a vehicle display apparatus, a theater display apparatus, a television, a wallpaper device, a signage device, a game device, a laptop computer, a monitor, a camera, a camcorder, a home appliances, etc.

A display apparatus according to various embodiments of the present disclosure may be described as follows.

A display apparatus according to embodiments of the present disclosure may include a display panel, a cover layer on the display panel, and a bonding layer including a main bonding layer on the cover layer and a nitrogen reactive bonding layer on the main bonding layer. A content of nitrogen atoms (N) of the nitrogen reactive bonding layer may be greater than a content of nitrogen atoms (N) of the main bonding layer.

According to various embodiments of the present disclosure, the nitrogen reactive bonding layer may have bonding between the nitrogen atoms.

According to various embodiments of the present disclosure, the nitrogen reactive bonding layer may include at least one of an azo compound, a diazo compound, and a pyrrole and imidazole compound.

According to various embodiments of the present disclosure, the nitrogen reactive bonding layer may be an ultraviolet reactive bonding layer.

According to various embodiments of the present disclosure, a wavelength range of the ultraviolet rays may range from 320 nm to 400 nm.

According to various embodiments of the present disclosure, the ultraviolet rays may be radiated at smaller than 5000 mJ/cm² at an output of 430 mW/cm².

According to various embodiments of the present disclosure, the cover layer may include glass. The adhesive strength between the main bonding layer and the cover layer may range from 1.0 kgf/inch to 4.0 kgf/inch.

According to various embodiments of the present disclosure, the adhesive strength between the main bonding layer and the cover layer may be smaller than 0.3 kgf/inch according to the reaction of the nitrogen reactive bonding layer with the ultraviolet rays.

According to various embodiments of the present disclosure, the nitrogen reactive bonding layer may include the azo compound or the diazo compound, and a weight ratio of the azo compound or the diazo compound may be 2 wt % or less. According to various embodiments of the present disclosure, the nitrogen reactive bonding layer may include the pyrrole and imidazole compound, and a weight ratio of the pyrrole and imidazole compound may be 5 wt % or less.

According to various embodiments of the present disclosure, the display panel may include a folding area, a first unfolding area disposed at one side of the folding area, and a second unfolding area disposed at the other side of the folding area.

A display apparatus according to embodiments of the present disclosure may include a display panel, a main bonding layer on the display panel, a cover layer on the main bonding layer, and a nitrogen reactive bonding layer on the cover layer. A content of nitrogen atom of the nitrogen reactive bonding layer may be greater than a content of nitrogen atom of the main bonding layer.

According to various embodiments of the present disclosure, the nitrogen reactive bonding layer may have bonding between the nitrogen atoms. The nitrogen reactive bonding layer may include at least one of an azo compound, a diazo compound, and a pyrrole and imidazole compound.

According to various embodiments of the present disclosure, the nitrogen reactive bonding layer may be an ultraviolet reactive bonding layer.

The display apparatus according to various embodiments of the present disclosure may further include a polarization layer between the display panel and the main bonding layer.

According to various embodiments of the present disclosure, the cover layer may include plastic. The adhesive strength between the main bonding layer and the polarization layer may be 0.8 kgf/inch or more.

According to various embodiments of the present disclosure, the adhesive strength between the main bonding layer and the polarization layer may be smaller than 0.5 kgf/inch according to the reaction of the nitrogen reactive bonding layer with the ultraviolet rays.

A display apparatus according to embodiments of the present disclosure may include a display panel, a first stretchable board on the display panel, a main bonding layer on the first stretchable board, a second stretchable board on the main bonding layer, and a nitrogen reactive bonding layer on the second stretchable board. A content of nitrogen atom of the nitrogen reactive bonding layer may be greater than a content of nitrogen atom of the main bonding layer.

According to various embodiments of the present disclosure, the nitrogen reactive bonding layer may have bonding between the nitrogen atoms. The nitrogen reactive bonding layer may include at least one of an azo compound, a diazo compound, and a pyrrole and imidazole compound. The nitrogen reactive bonding layer may an ultraviolet reactive bonding layer.

According to various embodiments of the present disclosure, adhesive strength between the main bonding layer and the first stretchable board may range from 1.0 kgf/inch to 3.0 kgf/inch. The adhesive strength between the main bonding layer and the first stretchable board may be smaller than 0.3 kgf/inch according to the reaction of the nitrogen reactive bonding layer with the ultraviolet rays.

According to various embodiments of the present disclosure, a thickness of the second stretchable board may range from 5 μm to 500 μm. A free volume fraction of the second stretchable board may be 50 or more.

A display apparatus according to embodiments of the present disclosure may include: a tray; a bonding layer on the tray; and a LED chip on the bonding layer, wherein the bonding layer comprises a base film, a nitrogen reactive bonding layer between the base film and the tray and a main bonding layer on the base film, wherein a content of nitrogen atom of the nitrogen reactive bonding layer is greater than a content of nitrogen atoms of the main bonding layer.

According to various embodiments of the present disclosure, the nitrogen reactive bonding layer has bonds between the nitrogen atoms, and the nitrogen reactive bonding layer includes at least one of an azo compound, a diazo compound, and a pyrrole and imidazole compound.

According to various embodiments of the present disclosure, the nitrogen reactive bonding layer includes the azo compound or the diazo compound, and a weight ratio of the azo compound or the diazo compound is 2 wt % or less.

According to various embodiments of the present disclosure, the nitrogen reactive bonding layer includes the pyrrole and imidazole compound, and a weight ratio of the pyrrole and imidazole compound is 5 wt % or less.

According to various embodiments of the present disclosure, the nitrogen reactive bonding layer is an ultraviolet reactive bonding layer.

According to various embodiments of the present disclosure, adhesive strength between the nitrogen reactive bonding layer and the tray is between 0.5 kgf/inch and 2.5 kgf/inch.

According to various embodiments of the present disclosure, the adhesive strength between the nitrogen reactive bonding layer and the tray is smaller than 0.3 kgf/inch according to the reaction of the nitrogen reactive bonding layer with the ultraviolet rays.

According to various embodiments of the present disclosure, a wavelength range of the ultraviolet rays ranges from 320 nm to 400 nm, and the ultraviolet rays are radiated at an energy density smaller than 5000 mJ/cm².

According to the embodiments of the present disclosure, since the bonding layer is formed as the nitrogen reactive bonding layer, the bonding layer can be easily peeled from the base substrate by nitrogen gases positioned on the interface with the base substrate.

What is claimed is:

1. A display apparatus comprising:
a display panel;
a main bonding layer on the display panel;
a cover layer on the main bonding layer; and
a nitrogen reactive bonding layer on the cover layer,
wherein a content of nitrogen atoms of the nitrogen reactive bonding layer is greater than a content of nitrogen atoms of the main bonding layer.

2. The display apparatus of claim 1, wherein the nitrogen reactive bonding layer comprises at least one bond between the nitrogen atoms, and wherein the nitrogen reactive bonding layer comprises at least one of an azo compound, a diazo compound, and a pyrrole and imidazole compound.

3. The display apparatus of claim 2, wherein the nitrogen reactive bonding layer comprises the azo compound or the diazo compound, and wherein a weight ratio of the azo compound or the diazo compound is 2 wt % or less.

4. The display apparatus of claim 2, wherein the nitrogen reactive bonding layer is an ultraviolet reactive bonding layer.

5. The display apparatus of claim 4, further comprising a polarization layer between the display panel and the main bonding layer.

6. The display apparatus of claim 5, wherein adhesive strength between the main bonding layer and the polarization layer is 0.8 kgf/inch or more.

7. The display apparatus of claim 6, wherein the adhesive strength between the main bonding layer and the polarization layer is less than 0.5 kgf/inch according to the reaction of the nitrogen reactive bonding layer with the ultraviolet rays.

8. The display apparatus of claim 4, wherein a wavelength range of the ultraviolet rays ranges from 320 nm to 400 nm.

9. The display apparatus of claim 8, wherein the ultraviolet rays are radiated at an energy density less than 5000 mJ/cm².

10. The display apparatus of claim 2, wherein the nitrogen reactive bonding layer comprises the pyrrole and imidazole compound, and wherein a weight ratio of the pyrrole and imidazole compound is 5 wt % or less.

11. A display apparatus comprising:
a display panel;
a cover layer on the display panel; and
a bonding layer comprising a main bonding layer on the cover layer and a nitrogen reactive bonding layer on the main bonding layer,
wherein a content of nitrogen atoms of the nitrogen reactive bonding layer is greater than a content of nitrogen atoms of the main bonding layer.

12. The display apparatus of claim 11, wherein the nitrogen reactive bonding layer comprises at least one bond between nitrogen atoms.

13. The display apparatus of claim 12, wherein the nitrogen reactive bonding layer comprises at least one of an azo compound, a diazo compound, and a pyrrole and imidazole compound.

14. The display apparatus of claim 13, wherein the nitrogen reactive bonding layer is an ultraviolet reactive bonding layer.

15. The display apparatus of claim 14, wherein adhesive strength between the main bonding layer and the cover layer ranges from 1.0 kgf/inch to 4.0 kgf/inch.

16. The display apparatus of claim 15, wherein the adhesive strength between the main bonding layer and the cover layer is less than 0.3 kgf/inch according to the reaction of the nitrogen reactive bonding layer with the ultraviolet rays.

17. A display apparatus comprising:
a display panel;
a first stretchable board on the display panel;
a main bonding layer on the first stretchable board;
a second stretchable board on the main bonding layer; and
a nitrogen reactive bonding layer on the second stretchable board,
wherein a content of nitrogen atoms of the nitrogen reactive bonding layer is greater than a content of nitrogen atoms of the main bonding layer.

18. The display apparatus of claim 17, wherein the nitrogen reactive bonding layer comprises at least one bond between nitrogen atoms,
the nitrogen reactive bonding layer comprises at least one of an azo compound, a diazo compound, and a pyrrole and imidazole, and
wherein the nitrogen reactive bonding layer is an ultraviolet reactive bonding layer.

19. The display apparatus of claim 18, wherein adhesive strength between the main bonding layer and the first stretchable board ranges from 1.0 kgf/inch to 3.0 kgf/inch, and adhesive strength between the main bonding layer and the first stretchable board is less than 0.3 kgf/inch according to the reaction of the nitrogen reactive bonding layer with the ultraviolet rays.

20. The display apparatus of claim 17, wherein a thickness of the second stretchable board ranges from 5 μm to 500 μm, and wherein a free volume fraction of the second stretchable board is 50 or more.
